(19) United States
(12) Patent Application Publication
(10) Pub. No.: US 2026/0007039 A1
(43) Pub. Date: Jan. 1, 2026

(54) DISPLAY DEVICE AND DISPLAY PANEL

(71) Applicant: LG Display Co., Ltd., Seoul (KR)

(72) Inventors: YongCheol KIM, Paju-si (KR); Sohee LEE, Paju-si (KR); Eunhyung LEE, Paju-si (KR)

(73) Assignee: LG Display Co., Ltd., Seoul (KR)

(21) Appl. No.: 19/239,514

(22) Filed: Jun. 16, 2025

(30) Foreign Application Priority Data
Jun. 26, 2024 (KR) 10-2024-0083327

(51) Int. Cl. H10K 59/80; G09G 3/3225

(52) U.S. Cl. CPC H10K 59/80523; G09G 3/3225; G09G 2300/0842; G09G 2354/00

(57) ABSTRACT

The present disclosure relates to a display device and a display panel. The present disclosure provides a display device including a display panel including a display area including an optical area in which at least one transmissive area and at least one light emitting area are defined, and a normal area located outside of the optical area and including a plurality of light emitting areas, a gate driving circuit configured to supply at least one gate signal to the display panel, a data driving circuit configured to convert image data into a data voltage and supplying the resulted data voltage to the display panel, and a display controller for controlling the gate driving circuit and the data driving circuit, the at least one transmissive area including an emission layer, a cohesive cathode layer disposed with a reference thickness at which self-aggregation occurs on the emission layer, and a capping layer disposed on the cohesive cathode layer.

### CROSS REFERENCE TO RELATED APPLICATION

This application claims priority from Korean Patent Application No. 10-2024-0083327, filed on Jun. 26, 2024 in the Korean Intellectual Property Office, which is hereby incorporated by reference for all purposes as if fully set forth herein.

### BACKGROUND

### Technical Field

The present disclosure relates to display devices and display panels, and more particularly, for example, without limitation, to display devices and display panels that are capable of improving transmittance of an area where an optical electronic device is located without a decrease in emission efficiency.

### Description of the Related Art

Recent advances in display technology have enabled display devices to provide increased functions, such as an image capture function, a sensing function, and the like, as well as an image display function. To provide these functions, a display device may need to include an optical electronic device, such as a camera, a light receiving device, a sensor for detecting an image, and the like.

To fully receive light passing through a front surface of a display device, it may be desirable for such an optical electronic device to be located in an area of the display device where incident light coming from the front surface can be increasingly received and detected. Taking account of this issue, typical display devices have employed a structure in which an optical electronic device is located in a front portion of the display devices to allow the optical electronic device to be effectively exposed to incident light. To install such an optical electronic device such as a camera, a sensor, and the like in a display device in this structure, a bezel of the display device may be increased, or a notch or a hole for accommodating the optical electronic device may be needed to be formed in a display area of a display panel.

Therefore, as a display device includes an optical electronic device that receives or detects incident light and performs an intended function, a size of the bezel in the front portion of the display device may be increased, or a substantial disadvantage may be encountered in designing the front portion of the display device.

In the field of display technology, work has been progressing on placing an optical electronic device such as a camera, a sensor, and the like in a display device without reducing an area of the display area of a display panel.

For example, in a display technology, even when an optical electronic device such as a camera, a sensor, and the like is placed under, or at a lower portion of, a display area of a display panel, and an optical area in which the optical electronic device is placed allows subpixels to be disposed, subpixels can be disposed only in light emitting areas of the optical area overlapping with the optical electronic device, but subpixels can not be disposed in the remaining transmissive areas except for the light emitting areas.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### BRIEF SUMMARY

However, when a cathode patterning material is formed in a transmissive area (which may be referred to as a light transmissive area) to dispose a cathode electrode in one or more light emitting areas in the optical area, a limitation on a material included in an emission layer may be imposed, thereby reducing emission efficiency.

To address these issues, the present inventors have discovered a display device and a display panel that are capable of improving transmittance of an area where one or more optical electronic devices are located without causing a decrease in emission efficiency.

Some embodiments of the present disclosure provide a display device and a display panel that include a structure where an organic material-metal complex, instead of a cathode patterning material, is formed in one or more transmissive areas in an optical area, thereby improving transmittance in the optical area.

Some embodiments of the present disclosure also provide a display device and a display panel that include a structure where organic material-metal complexes having different binding forces are formed in one or more light emitting areas and one or more transmissive areas in an optical area, thereby improving transmittance in the optical area without a decrease in emission efficiency.

Some embodiments provide a display device that includes a display panel including an optical area in which at least one transmissive area and at least one light emitting area are defined, and a normal area located outside of the optical area and including a plurality of light emitting areas, a gate driving circuit configured to supply at least one gate signal to the display panel, a data driving circuit configured to convert image data into a data voltage and supplying the resulted data voltage to the display panel, and a display controller configured to control the gate driving circuit and the data driving circuit. In some embodiments, the at least one transmissive area may include an emission layer, a cohesive cathode layer disposed with a reference thickness at which self-aggregation occurs on the emission layer, and a capping layer disposed on the cohesive cathode layer.

Some embodiments provide a display panel that includes a display area including an optical area in which at least one transmissive area and at least one light emitting area are defined, and a normal area located outside of the optical area and including a plurality of light emitting areas. In some embodiments, the at least one transmissive area may include a first emission layer, a cohesive cathode layer disposed with a reference thickness at which self-aggregation occurs on the first emission layer, and a first capping layer disposed on the cohesive cathode layer, and the at least one light emitting area and at least one of the plurality of light emitting areas may include an anode electrode, a second emission layer disposed on the anode electrode, an organic cathode layer disposed on the second emission layer and allowing an organic material and a cathode electrode to be stacked, and a second capping layer disposed on the organic cathode layer.

According to some embodiments of the present disclosure, a display device and a display panel may be provided that are capable of improving transmittance of an area where one or more optical electronic devices are located without a decrease in emission efficiency.

According to some embodiments of the present disclosure, a display device and a display panel may be provided that include a structure where an organic material-metal complex instead of a cathode patterning material is formed in one or more transmissive areas in an optical area, thereby improving transmittance in the optical area.

According to some embodiments, a display device and a display panel may be provided that include a structure where organic material-metal complexes having different bonding strengths are formed in one or more light emitting areas and one or more transmissive areas in an optical area, thereby improving transmittance in the optical area without a decrease in emission efficiency.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 is a plan view of an example display device according to some embodiments of the present disclosure;

FIG. 2 illustrates an example system configuration of the display device according to some embodiments of the present disclosure;

FIG. 3 illustrates an example equivalent circuit of each, or one or more, of subpixels included in a display panel according to some embodiments of the present disclosure;

FIG. 4 illustrates example subpixel arrangements in three areas included in a display area of the display panel according to some embodiments of the present disclosure;

FIG. 5 illustrates the structure of an example light emitting element according to energy level in the display panel according to some embodiments of the present disclosure;

FIG. 6 is a cross-sectional view of an example optical area defined in the display panel according to some embodiments of the present disclosure;

FIG. 7 illustrates example structures of a light emitting area and an area corresponding to the light emitting area in a transmissive area in the display panel according to some embodiments of the present disclosure;

FIG. 8 illustrates an example molecular structure of at least one bondable organic layer located on and/or underneath a cohesive cathode electrode in a light emitting area of the display panel according to some embodiments of the present disclosure;

FIG. 9 illustrates electron micrographs and transmittance of a light emitting area and a transmissive area including a cohesive cathode electrode in the display panel according to some embodiments of the present disclosure;

FIG. 10 illustrates another example structures of a light emitting area and an area corresponding to the light emitting area in a transmissive area in the display panel according to some embodiments of the present disclosure;

FIG. 11 illustrates an example molecular structure of a cohesive organic layer located on and/or underneath a cohesive cathode electrode in a transmissive area of the display panel according to some embodiments of the present disclosure;

FIG. 12 illustrates an example structure including a cathode electrode of a stack structure in a light emitting area and a transmissive area of the display panel according to some embodiments of the present disclosure;

FIG. 13 illustrates another example structure including a cathode electrode of a stack structure in a light emitting area and a transmissive area of the display panel according to some embodiments of the present disclosure; and

FIG. 14 illustrates an example structure including a bondable organic layer having a pattern form and a cathode electrode of a stack structure in a light emitting area and a transmissive area of the display panel according to some embodiments of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Hereinafter, some embodiments of the present disclosure will be described in detail with reference to the accompanying drawings. Reference will now be made in detail to embodiments of the present disclosure, examples or aspects of which may be illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Further, in the following description of examples or embodiments of the present disclosure, detailed descriptions of well-known functions and components incorporated herein will be omitted or may be briefly discussed when it is determined that the description may make the subject matter in some embodiments of the present disclosure rather unclear. Where the terms “include,” “have,” “include,” “contain,” “constitute,” “compose, “make up of,” “formed of,” and the like are used, one or more other elements may be added unless the term, such as “only,” is used. An element described in the singular form is intended to include a plurality of elements, and vice versa, unless the context clearly indicates otherwise.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments may be provided so that this disclosure may be sufficiently thorough and complete to assist those skilled in the art to fully understand the scope of the present disclosure. Further, the present disclosure is only defined by scopes of claims.

Throughout the drawings and the detailed description, unless otherwise described, the same drawing reference numerals should be understood to refer to the same elements, features, and structures. The relative size and depiction of these elements may be exaggerated for clarity, illustration, and convenience. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Any implementation described herein as an “example” is not necessarily to be construed as preferred or advantageous over other implementations.

In the description of the various embodiments of the present disclosure, where positional relationships are described, for example, when a position relation between two parts is described as, for example, “on,” “over,” “under,” and “next,” or the like, one or more other parts may be located between the two parts unless a more limiting term, such as “just” or “direct(ly)” is used. For example, where an element or layer is disposed “on” another element or layer, a third layer or element may be interposed therebetween.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Hereinafter, various embodiments of the present disclosure will be described in detail with reference to the accompanying drawings.

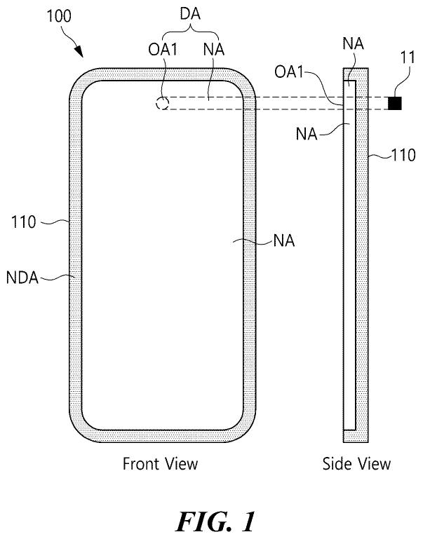

FIG. 1 is a plan view of a display device according to the present disclosure.

In the embodiment of FIG. 1, a display device 100 may include a display panel 110 for displaying images, and one or more optical electronic devices (11 and/or 12).

The display panel 110 may include a display area DA in which images can be displayed and a non-display area NDA in which an image is not displayed.

A plurality of subpixels may be disposed in the display area DA, and several types of signal lines for driving the plurality of subpixels may be disposed in the display area DA.

The non-display area NDA may represent an area outside of the display area DA. Several types of signal lines may be disposed in the non-display area NDA, and several types of driving circuits may be connected to, or located in the non-display area NDA. At least a portion of the non-display area NDA may be bent, and thereby, be invisible from the front surface of the display device 100 or be covered by a case or housing (not shown) of the display device 100. The non-display area NDA may be also referred to as a non-active area, a bezel, or a bezel area.

Referring to FIG. 1, the one or more optical electronic devices (11 and/or 12) included in the display device 100 may be located under, or in a lower portion of, the display panel 110 (an opposite side to the viewing surface of the display panel 110).

In this implementation, light may enter the front surface (viewing surface) of the display panel 110, pass through the display panel 110, and reach the one or more optical electronic devices (11 and/or 12) located under, or in the lower portion of, the display panel 110 (the opposite side to the viewing surface).

The one or more optical electronic devices (11 and/or 12) may be devices capable of receiving or detecting light passing through the display panel 110 and performing a predefined function based on the received light. For example, the one or more optical electronic devices (11 and/or 12) may include one or more of the following: an image capture device such as a camera (an image sensor), and/or the like; or a sensor such as a proximity sensor, an illuminance sensor, and/or the like.

Referring to FIG. 1, the display area DA of the display panel 110 may include a normal area NA and one or more optical areas (OA1 and/or OA2).

Referring to FIG. 1, the one or more optical areas (OA1 and/or OA2) may be one or more areas respectively overlapping with the one or more optical electronic devices (11 and/or 12).

According to an example of FIG. 1, the display area DA may include a normal area NA and a first optical area OA1. In this implementation, at least a portion of the first optical area OA1 may overlap with a first optical electronic device 11.

When the display device 100 has a structure in which the first optical electronic device 11 such as a camera, and the like, is located under, or in a lower portion of, the display panel 110 without being exposed to the outside, the display device 100 configured with this structure may be referred to as a display in which under-display camera (UDC) technology is implemented.

According to this implementation, the display device 100 can provide an advantage of preventing or reducing a reduction in the size of the display area DA because a notch or a camera hole for exposing a camera and the like need not be formed in the display panel 110.

Indeed, since a notch or a camera hole for camera exposure need not be formed in the display panel 110, the display device 100 can provide further advantages of reducing the size of a bezel area, and improving the degree of freedom in design because such limitations to the design are removed.

It should be noted here that although the one or more optical electronic devices (11 and/or 12) are located on the back of (e.g., under, or in a lower portion of) the display panel 110 of the display device 100 (e.g., hidden or not to be exposed to the outside), the one or more optical electronic devices (11 and/or 12) are needed to fully receive or detect light to perform normally predefined functionalities.

Further, even when one or more optical electronic devices (11 and/or 12) included in the display device 100 are located on the back of (e.g., under, or in a lower portion of) the display panel 110 to be hidden and located to be overlap with the display area DA, it is necessary for image display to be normally performed in the one or more optical areas (OA1 and/or OA2) overlapping with the one or more optical electronic devices (11 and/or 12) in the display area DA. As discussed below, the display device 100 of the present disclosure can provide image displaying in a normal manner (e.g., without reduction in image quality) in the one or more optical areas (OA1 and/or OA2) overlapping with the one or more optical electronic devices (11 and/or 12) in the display area DA even when one or more optical electronic devices (11 and/or 12) are located on the back of the display panel.

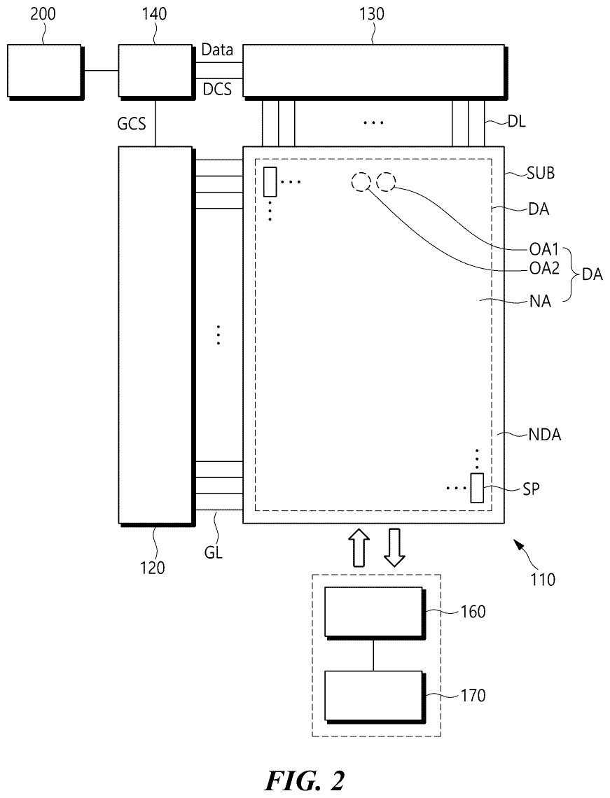

FIG. 2 illustrates a system configuration of the display device 100 according to the present disclosure.

Referring to FIG. 2, the display device 100 may include the display panel 110 and at least one display driving circuit as components for displaying an image.

The at least one display driving circuit may be at least one circuit for driving the display panel 110. For example, the at least one display driving circuit may include a gate driving circuit 120, a data driving circuit 130, a display controller 140, and the like.

The display panel 110 may include a display area DA in which images can be displayed and a non-display area NDA in which an image is not displayed. The non-display area NDA may be an area outside of the display area DA, and may also be referred to as an edge area or a bezel area. All or a portion of the non-display area NDA may be an area visible from the front surface of the display device 100, or an area not visible from the front surface of the display device 100 as a corresponding portion is bent.

The display panel 110 may include a substrate SUB and a plurality of subpixels SP disposed on the substrate SUB. The display panel 110 may further include several types of signal lines to drive the plurality of subpixels SP.

In some embodiments, the display device 100 may be a liquid crystal display device, a self-emission display device in which light is emitted from the display panel 110 itself, or the like. When the display device 100 is a self-emission display device, each of the plurality of subpixels SP may include a light emitting element.

For example, the display device 100 may be an organic light emitting display device in which the light emitting element is implemented with an organic light emitting diode (OLED). In another example, the display device 100 may be an inorganic light emitting display device in which the light emitting element is implemented with an inorganic material-based light emitting diode. In another example, the display device 100 may be a quantum dot display device in which the light emitting element is implemented using quantum dots, which are self-emission semiconductor crystals.

Each, or one or more, of the plurality of subpixels SP included in the display device 100 may have a different structure depending on which type of the display device 100 is implemented. For example, when the display device 100 is a self-emission display device including self-emission subpixels SP, each subpixel SP may include a self-emission light emitting element, one or more transistors, and one or more capacitors.

The several types of signal lines disposed in the display device 100 may include, for example, a plurality of data lines DL for carrying data signals (which may be also referred to as data voltages or image signals), a plurality of gate lines GL for carrying gate signals (which may be also referred to as scan signals), and the like.

The plurality of data lines DL and the plurality of gate lines GL may intersect each other. Each of the plurality of data lines DL may be disposed to extend in a first direction. Each of the plurality of gate lines GL may be disposed to extend in a second direction.

For example, the first direction may be a column or vertical direction, and the second direction may be a row or horizontal direction. In another example, the first direction may be the row direction, and the second direction may be the column direction.

The data driving circuit 130 may be a circuit for driving the plurality of data lines DL, and can supply data signals to the plurality of data lines DL. The gate driving circuit 120 may be a circuit for driving the plurality of gate lines GL, and can supply gate signals to the plurality of gate lines GL.

The display controller 140 may be a device for controlling the data driving circuit 130 and the gate driving circuit 120, and can control driving timing for the plurality of data lines DL and driving timing for the plurality of gate lines GL.

The display controller 140 can supply a data driving control signal DCS to the data driving circuit 130 to control the data driving circuit 130, and supply a gate driving control signal GCS to the gate driving circuit 120 to control the gate driving circuit 120.

The display controller 140 can receive input image data from a host system 200 and supply image data (Data) based on the input image data to the data driving circuit 130.

The data driving circuit 130 can supply data signals to the plurality of data lines DL according to the driving timing control of the display controller 140.

The data driving circuit 130 can receive the digital image data Data from the display controller 140, convert the received image data Data into analog data signals, and supply the resulting analog data signals to the plurality of data lines DL.

The gate driving circuit 120 can supply gate signals to the plurality of gate lines GL according to the timing control of the display controller 140. The gate driving circuit 120 can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In some embodiments, the data driving circuit 130 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, some embodiments of the present disclosure are not limited thereto.

In one or more embodiments, the gate driving circuit 120 may be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. However, some embodiments of the present disclosure are not limited thereto.

In some embodiments, the gate driving circuit 120 may be disposed in the non-display area NDA of the display panel 110 by a gate-in-panel (GIP) technique. The gate driving circuit 120 may be disposed on a substrate, or connected to the substrate. For example, the gate driving circuit 120 implemented by the gate-in-panel (GIP) technique may be disposed in a portion of the non-display area NDA of the substrate. In some embodiments, the gate driving circuit 120 may be connected to the substrate when the gate driving circuit 120 is implemented by the chip-on-glass (COG) technique, the chip-on-film (COF) technique, or the like.

In some embodiments, at least one of the data driving circuit 130 and the gate driving circuit 120 may be disposed in the display area DA. For example, at least one of the data driving circuit 130 and the gate driving circuit 120 may be disposed not to overlap with subpixels SP, or be disposed to overlap with one or more, or all, of the subpixels SP.

The data driving circuit 130 may be located in, and/or electrically connected to, but not limited to, only one side or edge (e.g., an upper portion or a lower portion) of the display panel 110. In some embodiments, the data driving circuit 130 may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The gate driving circuit 120 may be located in, and/or electrically connected to, but not limited to, only one side or edge (e.g., a left portion or a right portion) of the display panel 110. In some embodiments, the gate driving circuit 120 may be disposed in, and/or electrically connected to, but not limited to, two sides or edges (e.g., a left portion and a right portion) of the display panel 110 or at least two of four sides or edges (e.g., the left portion, the right portion, an upper portion, and a lower portion) of the display panel 110 according to driving schemes, panel design schemes, or the like.

The display controller 140 may be implemented in a separate component from the data driving circuit 130, or integrated with the data driving circuit 130, so that the display controller 140 and the data driving circuit 130 can be implemented in a single integrated circuit.

The display controller 140 may be a timing controller used in the typical display technology or a control apparatus/device capable of additionally performing other control functionalities in addition to the typical function of the timing controller. In one or more embodiments, the display controller 140 may be one or more other control circuits different from the timing controller, or a circuit or component in the control apparatus/device. The display controller 140 may be implemented with various circuits or electronic components such as an integrated circuit (IC), a field programmable gate array (FPGA), an application specific integrated circuit (ASIC), a processor, and/or the like.

The display controller 140 may be mounted on a printed circuit board, a flexible printed circuit, and/or the like and be electrically connected to the gate driving circuit 120 and the data driving circuit 130 through the printed circuit board, flexible printed circuit, and/or the like.

The display controller 140 may transmit signals to, and receive signals from, the data driving circuit 130 via one or more predetermined interfaces. For example, such interfaces may include, a low voltage differential signaling (LVDS) interface, an embedded clock point-point interface (EPI), a serial peripheral interface (SP), and the like.

In one or more example embodiments, to further provide a touch sensing function, as well as an image display function, the display device 100 may include at least one touch sensor, and a touch circuit configured to detect whether a touch event occurs, which is caused by a touch object such as a finger, a pen, or the like, or to detect a corresponding touch position, by sensing the touch sensor. It should be noted herein that a touch sensor may be referred to as all, or one or more, of a plurality of touch electrodes included in the display panel 110 according to design requirements.

The touch circuit may include a touch driving circuit 160 configured to generate and provide touch sensing data by driving and sensing the touch sensor, a touch controller 170 configured to detect the occurrence of a touch event or detect a touch position based on the touch sensing data, and one or more other components.

In some embodiments, the touch sensor may include a plurality of touch electrodes. The touch sensor may further include a plurality of touch lines for electrically connecting the plurality of touch electrodes to the touch driving circuit 160.

The touch sensor may be added to the outside of the display panel 110 in the form of a touch panel, or be integrated to the inside of the display panel 110. The touch sensor added to the outside of the display panel 110 in the form of the touch panel may be referred to as an add-on type of touch sensor. In the example where the add-on type of touch sensor is employed, a corresponding touch panel and the display panel 110 may be separately manufactured and coupled during an assembly process. The add-on type of touch panel may include a touch panel substrate and a plurality of touch electrodes on the touch panel substrate.

In the example where the touch sensor is integrated to the inside of the display panel 110, the touch sensor may be formed over the substrate SUB together with signal lines and electrodes related to driving the display device 100 during the process of manufacturing the display panel 110.

The touch driving circuit 160 can supply a touch driving signal to at least one of a plurality of touch electrodes, sense at least one of the plurality of touch electrodes, and generate touch sensing data based on a result from the sensing.

The touch circuit can perform touch sensing by a self-capacitance sensing technique or a mutual-capacitance sensing technique.

In the example where the touch circuit performs touch sensing by the self-capacitance sensing technique, the touch circuit can perform touch sensing based on capacitance between each touch electrode and a touch object (e.g., a finger, a pen, and the like).

According to the self-capacitance sensing technique, each of the plurality of touch electrodes may serve as both a driving touch electrode and a sensing touch electrode. The touch driving circuit 160 may drive all, or one or more, of the plurality of touch electrodes and sense all, or one or more, of the plurality of touch electrodes.

In the example where the touch circuit performs touch sensing by the mutual-capacitance sensing technique, the touch circuit can perform touch sensing based on capacitance between touch electrodes.

According to the mutual-capacitance sensing technique, the plurality of touch electrodes may be divided into one or more driving touch electrodes and one or more sensing touch electrodes. The touch driving circuit 160 can drive the driving touch electrodes and sense the sensing touch electrodes.

In some embodiments, the touch driving circuit 160 and the touch controller 170 included in the touch circuit may be implemented in separate devices or be integrated into a single device. In some embodiments, the touch driving circuit 160 and the data driving circuit 130 may be implemented in separate devices, or be integrated into a single device.

The display device 100 may further include a power supply circuit configured to supply several types of power to the display driving circuit and/or the touch circuit.

In some embodiments, the display device 100 may be a mobile terminal such as a smart phone, a tablet, or the like, or a monitor, a television (TV), or the like. Such apparatuses may be configured in various types, sizes, and shapes. The display device 100 according to some embodiments are not limited thereto, and may include various types, sizes, and shapes configured to display information or images. A display apparatus according to the present disclosure may be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

As described above with reference to FIG. 1, the display area DA of the display panel 110 may include the normal area NA and the one or more optical areas (OA1 and/or OA2).

The normal area NA and the one or more optical areas (OA1 and/or OA2) may be areas where images can be displayed. It should be noted here that the normal NA may be an area in which a light transmissive structure need not be implemented, and the one or more optical areas (OA1 and/or OA2) may be areas in which a light transmissive structure need be implemented.

As discussed above with reference to FIG. 1, even though the display area DA of the display panel 110 may include the one or more optical areas (OA1 and/or OA2) together with the normal area NA, for convenience of description, discussions that follow will be provided based on examples where the display area DA includes both first and second optical areas (OA1 and OA2).

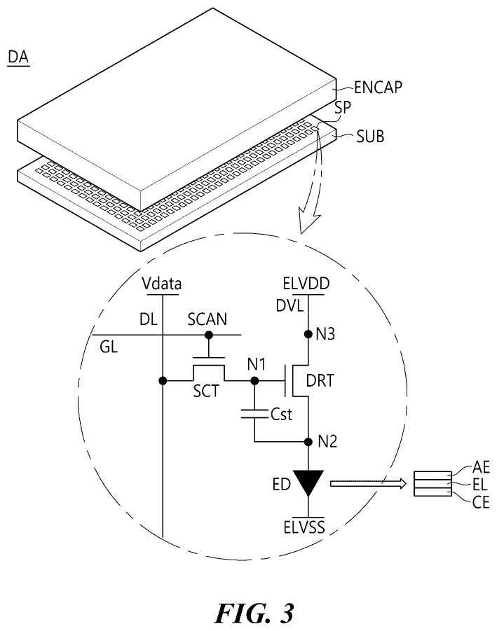

FIG. 3 illustrates an example equivalent circuit of each, or one or more, of subpixels included in the display panel 110 according to some embodiments.

Referring to FIG. 3, in one or more example embodiments, each of subpixels SP disposed in a normal area NA (e.g., the normal area NA of FIG. 1), a first optical area OA1 (e.g., the first optical area OA1 of FIG. 1), and a second optical area OA2 included in the display area DA of the display panel 110 may include a light emitting element ED, a driving transistor DRT for driving the light emitting element ED, a scan transistor SCT for allowing a data voltage Vdata to be applied to a first node N1 of the driving transistor DRT, a storage capacitor Cst for maintaining a voltage at an approximate constant level during one frame or one or more of periods including in one frame, and the like.

The driving transistor DRT may include the first node N1 to which a data voltage Vdata is applied, a second node N2 electrically connected to the light emitting element ED, and a third node N3 to which a driving voltage ELVDD through a driving voltage line DVL is applied. In the driving transistor DRT, the first node N1 may be a gate node, the second node N2 may be a source node or a drain node, and the third node N3 may be the drain node or the source node.

The light emitting element ED may include an anode electrode AE, an emission layer EL, and a cathode electrode CE. The anode electrode AE may be a pixel electrode disposed in each subpixel SP, and be electrically connected to the second node N2 of the driving transistor DRT of each subpixel SP. The cathode electrode CE may be a common electrode commonly disposed in a plurality of subpixels SP, and a base voltage ELVSS such as a low level of voltage may be applied to the cathode electrode CE.

For example, the anode electrode AE may be a pixel electrode, and the cathode electrode CE may be a common electrode. In another example, the anode electrode AE may be a common electrode, and the cathode electrode CE may be a pixel electrode. For convenience of description, discussions that follow will be provided based on examples where the anode electrode AE is a pixel electrode, and the cathode electrode CE is a common electrode unless explicitly stated otherwise. However, it should be understood that the scope of the present disclosure includes examples where the anode electrode AE is a common electrode, and the cathode electrode CE is a pixel electrode.

The light emitting element ED may be, for example, an organic light emitting diode (OLED), an inorganic light emitting diode (LED), a quantum dot (QD) light emitting element, a micro light emitting diode, a mini light emitting diode, or the like, but some embodiments are not limited thereto. In the example where an organic light emitting diode (OLED) is used as the light emitting element ED, the emission layer EL included in the light emitting element ED may include an organic emission layer including an organic material.

The scan transistor SCT may be turned on and off by a scan signal SCAN, which is a gate signal applied through a gate line GL, and be electrically connected between the first node N1 of the driving transistor DRT and a data line DL.

The storage capacitor Cst may be electrically connected between the first node N1 and the second node N2 of the driving transistor DRT.

Each pixel SP may include two transistors (2T: DRT and SCT) and one capacitor (1C: Cst) (which may be referred to as a “2T1C structure”) as shown in FIG. 3. In some implementations, each pixel SP may further include one or more transistors, or further include one or more capacitors.

In some embodiments, the storage capacitor Cst may be an external capacitor intentionally configured or designed to be located outside of the driving transistor DRT, other than internal capacitors such as parasitic capacitors (e.g., a gate-to-source capacitance Cgs, a gate-to-drain capacitance Cgd, and the like) that may be present between the first node N1 and the second node N2 of the driving transistor DRT.

Each of the driving transistor DRT and the scan transistor SCT may be an n-type transistor or a p-type transistor.

Since some circuit elements (in particular, a light emitting element ED) in each subpixel SP can be easily damaged to external moisture or oxygen, an encapsulation layer ENCAP may be disposed in the display panel 110 to prevent or reduce the external moisture or oxygen from penetrating into such circuit elements (in particular, the light emitting element ED). The encapsulation layer ENCAP may be disposed such that it covers the light emitting element ED.

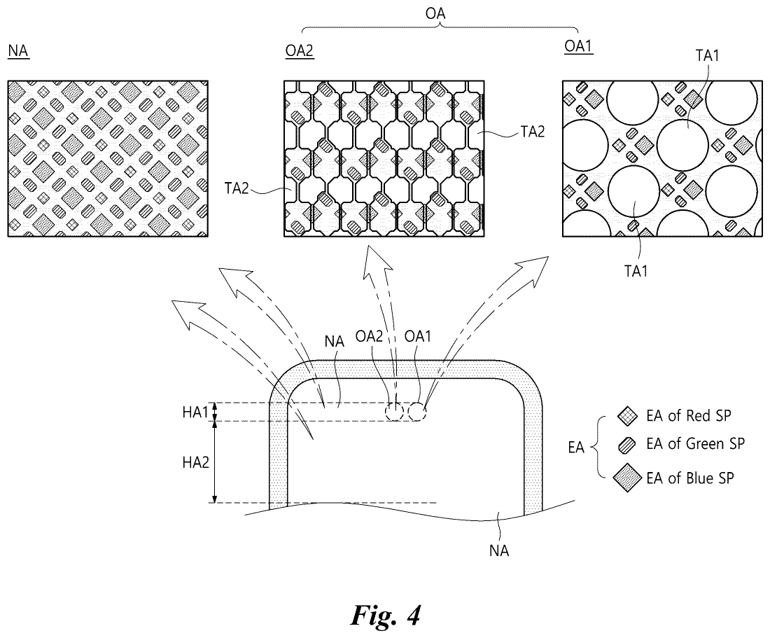

FIG. 4 illustrates example subpixel arrangements in three areas included in the display area DA of the display panel 110 according to some embodiments.

Referring to FIG. 4, in one or more example embodiments, a plurality of subpixels SP may be disposed in each of a normal area NA (e.g., the normal area NA of FIG. 1), a first optical area OA1 (e.g., the first optical area OA1 of FIG. 1), and a second optical area OA2 included in the display area DA of the display panel 110.

The plurality of subpixels SP may include, for example, at least one red subpixel (Red SP) emitting red light, at least one green subpixel (Green SP) emitting green light, and at least one blue subpixel (Blue SP) emitting blue light.

Accordingly, each of the normal area NA, the first optical area OA1, and the second optical area OA2 may include one or more light emitting areas EA of one or more red subpixels (Red SP), one or more light emitting areas EA of one or more green subpixels (Green SP), and one or more light emitting areas EA of one or more blue subpixels (Blue SP).

It should be understood here that the normal area NA may not include a light transmissive structure, but include light emitting areas EA.

In contrast, it may be desirable that the first optical area OA1 and the second optical area OA2 include both light emitting areas EA and light transmissive structures.

Accordingly, in some embodiments, the first optical area OA1 may include one or more light emitting areas EA and one or more first transmissive areas TA1, and the second optical area OA2 may include one or more light emitting areas EA and one or more second transmissive areas TA2.

In some embodiments, the light emitting areas EA and the transmissive areas (TA1 and TA2) may be distinct according to whether light is allowed to be transmitted. For example, the light emitting areas EA may be areas not allowing light to be transmitted (e.g., not allowing light to pass through a stack structure of the display panel 110), and the transmissive areas (TA1 and TA2) may be areas allowing light to be transmitted (e.g., allowing light to pass through a stack structure of the display panel 110).

In some embodiments, the light emitting areas EA and the transmissive areas (TA1 and TA2) may be also distinct according to whether or not a specific metal layer is included. For example, a cathode electrode CE (e.g., the cathode electrode CE illustrated in FIG. 3) may be disposed in the light emitting areas EA, and a cathode electrode CE may not be disposed in the transmissive areas (TA1 and TA2). For example, a light shield layer may be disposed in the light emitting areas EA, and a light shield layer may not be disposed in the transmissive areas (TA1 and TA2).

Since the first optical area OA1 includes the first transmissive areas TA1 and the second optical area OA2 includes the second transmissive areas TA2, both of the first optical area OA1 and the second optical area OA2 may be areas through which light can be transmitted.

In some embodiments, a transmittance (a degree of transmission) of the first optical area OA1 and a transmittance (a degree of transmission) of the second optical area OA2 may be substantially the same as each other.

For example, each, or one or more, of the first transmissive areas TA1 of the first optical area OA1 and each, or one or more, of the second transmissive areas TA2 of the second optical area OA2 may have substantially the same shape or size as each other. In another example, even when each, or one or more, of the first transmissive areas TA1 of the first optical area OA1 and each, or one or more, of the second transmissive areas TA2 of the second optical area OA2 have different shapes or sizes, a ratio of each, or one or more, of the first transmissive areas TA1 to the first optical area OA1 and a ratio of each, or one or more, of the second transmissive areas TA2 to the second optical area OA2 may be substantially the same as each other.

In some embodiments, a transmittance (a degree of transmission) of the first optical area OA1 and a transmittance (a degree of transmission) of the second optical area OA2 may be different from each other.

For example, each, or one or more, of the first transmissive areas TA1 of the first optical area OA1 and each, or one or more, of the second transmissive areas TA2 of the second optical area OA2 may have different shapes or sizes from each other. In another example, even when each, or one or more, of the first transmissive areas TA1 of the first optical area OA1 and each, or one or more, of the second transmissive areas TA2 of the second optical area OA2 have substantially the same shape or size, a ratio of each, or one or more, of the first transmissive areas TA1 to the first optical area OA1 and a ratio of each, or one or more, of the second transmissive areas TA2 to the second optical area OA2 may be different from each other.

For example, in the example where a first optical electronic device 11 overlapping with the first optical area OA1 is a camera, and a second optical electronic device 12 overlapping with the second optical area OA2 is a sensor for detecting images, the camera may need a greater amount of light than the sensor.

According to this configuration, the transmittance (degree of transmission) of the first optical area OA1 may be greater than the transmittance (degree of transmission) of the second optical area OA2.

For example, each, or one or more, of the first transmissive areas TA1 of the first optical area OA1 may have a size greater than each, or one or more, of the second transmissive areas TA2 of the second optical area OA2. In another example, even when each, or one or more, of the first transmissive areas TA1 of the first optical area OA1 and each, or one or more, of the second transmissive areas TA2 of the second optical area OA2 have substantially the same size, a ratio of each, or one or more, of the first transmissive areas TA1 to the first optical area OA1 may be greater than a ratio of each, or one or more, of the second transmissive areas TA2 to the second optical area OA2.

For convenience of description, discussions that follow are provided based on an example in which the transmittance (degree of transmission) of the first optical area OA1 is greater than the transmittance (degree of transmission) of the second optical area OA2.

Further, the transmissive areas (TA1 and TA2) may be referred to as transparent areas and the term transmittance may be referred to as transparency.

Further, in discussions that follow, it is assumed that the first optical areas OA1 and the second optical areas OA2 are located in an upper edge of the display area DA of the display panel 110, and are disposed to be horizontally adjacent to each other in a direction in which the upper edge extends unless explicitly stated otherwise.

A horizontal display area in which the first optical area OA1 and the second optical area OA2 are disposed may be referred to as a first horizontal display area HA1, and another horizontal display area in which the first optical area OA1 and the second optical area OA2 are not disposed may be referred to as a second horizontal display area HA2.

The first horizontal display area HA1 may include the normal area NA, the first optical area OA1, and the second optical area OA2. The second horizontal display area HA2 may include only the normal area NA.

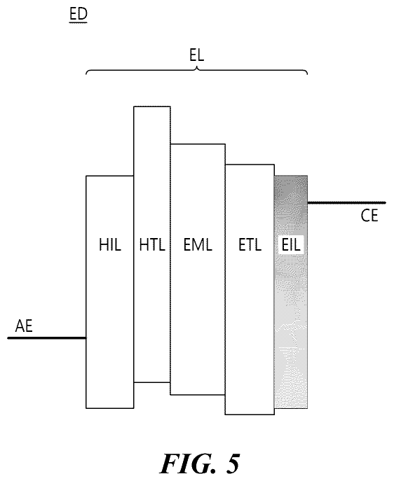

FIG. 5 illustrates the structure of an example light emitting element according to energy level in the display panel 110 according to some embodiments.

Referring to FIG. 5, in the display panel 110 according to some embodiments, a light emitting element ED may include an emission layer EL, a cathode electrode CE and an anode electrode AE facing each other with the emission layer EL interposed therebetween.

The emission layer EL may include an emission material layer EML, and may further include a hole injection layer HIL, a hole transport layer HTL, an electron transport layer ETL, an electron injection layer EIL, and the like. Further, the emission layer EL may further include an electron blocking layer EBL and a hole blocking layer HBL.

The light emitting element ED can emit light by energy from excitons generated during the excitation process when holes injected into the anode electrode AE and electrons injected into the cathode electrode CE recombine in emission material layer EML.

The anode electrode AE may include a conductive material having a relatively large work function value. For example, the anode electrode AE may include ITO, IZO, ITZO, SnO, ZnO, ICO, AZO, and/or a combination thereof.

The hole injection layer HIL may be located between the anode electrode AE and the hole transport layer HTL, and can improve an interface characteristic between the anode electrode AE and the hole transport layer HTL. For example, the hole injection layer HIL may include MTDATA, NATA, ITNATA, 2T-NATA, CuPc, TCTA, NPB(NPD), DNTPD, HAT-CN, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB, MgF2, CaF2, and/or a combination thereof.

The hole transport layer HTL can supply holes to the emission material layer EML. The hole transport layer HTL may include TPD, NPB, DNTPD, BPBPA, CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl) biphenyl)-4-amine, N-([1,1′-biphenyl]-4-yl)-9,9-dimethyl-N-(4-(9-phenyl-9H-carbazol-3-yl)phenyl)-9H-fluoren-2-amine, and/or a combination thereof.

The emission material layer EML may include a red emission material layer, a green emission material layer, and a blue emission material layer.

The electron transport layer ETL can supply electrons to the emission material layer EML. The electron transport layer ETL may include any one of an oxadiazole-based compound, a triazole-based compound, a phenanthroline-based compound, a benzoxazole-based compound, a benzothiazole-based compound, a benzimidazole-based compound, and a triazine-based compound.

The electron injection layer EIL may be located between the cathode electrode CE and the electron transport layer ETL, and can improve the characteristic of the cathode electrode CE and the lifetime of the light emitting element ED. The electron injection layer EIL may include an alkali metal halide-based material such as LiF, CsF, NaF, BaF2, or the like, and/or an alkaline earth metal halide-based material, and/or an organometallic material such as Liq, lithium benzoate, sodium stearate, or the like.

In some embodiments, to increase the emission efficiency of the light emitting element ED, the electron injection layer EIL may include a film-forming structure of ytterbium (Yb) and lithium fluoride (LiF).

The cathode electrode CE may be located in all or at least part of the display area DA and include a material having a relatively low work function value. For example, the cathode electrode CE may include aluminum (Al), magnesium (Mg), calcium (ca), silver (Ag), an alloy thereof, and/or a combination thereof (for example, a material having good reflective properties such as an aluminum-magnesium alloy (AlMg)).

Meanwhile, to improve transmittance of transmissive areas TA, the display panel 110 may include a structure in which a cathode patterning material is disposed in at least one transmissive area TA where at least one optical electronic device (e.g., the first optical electronic device 11, and/or the second optical electronic device 12 discussed above) is located, so that a corresponding cathode electrode CE is not disposed in the transmissive area TA and is disposed only in at least one light emitting area EA.

The cathode patterning material formed in the transmissive area TA may include a fluorine-based organic material. For example, the cathode patterning material may include a perfluorinated material such as Perfluorooctyl-trichlorosilane, Perfluorodecyltrichlorosilane (FDTS), a high-fluorinated monomer, oligomer material, and a polymer material such as Polytetrafluoroethylene (PTFE), or the like.

In some embodiments, the cathode patterning material may include a fluorinated molecule having one or more —CF3 groups attached to the rest of the fluorinated molecule. The —CF2 functional group, in which two fluorine atoms are bonded to a carbon atom, may have a surface energy of about 18 mJ/m2, which is relatively low compared to the surface energy of most inorganic materials including a metal.

Further, since the —CF3 functional group, in which three fluorine atoms are bonded, may have a very low surface energy of about 6 mJ/m2, a cathode electrode CE may be suppressed from being formed in transmissive area TA by the cathode patterning material including the fluorine-based molecule having the —CF3 group.

However, the formation of the cathode electrode CE in the transmissive area TA may not be completely suppressed by the cathode patterning material, and therefore, some residual film may remain in the transmissive area TA during the process of forming the cathode electrode CE.

Further, it should be understood that when the cathode patterning material is formed in the transmissive area TA, it may be difficult to use a fluorine-based compound such as lithium fluoride (LiF) in the electron injection layer EIL located under the cathode electrode CE.

Thereby, an energy level of the electron injection layer EIL may be lowered, which may cause the recombination of holes and electrons in the emission material layer EML to become difficult. As a result, the electron injection layer EIL may be formed in a single metal layer such as ytterbium (Yb), which may cause the emission efficiency of the light emitting element ED to be reduced.

To address these issues, in some embodiments, the display panel 110 may include a structure in which a cohesive cathode electrode is disposed in at least one transmissive area TA where at least one optical electronic device (e.g., the first optical electronic device 11, and/or the second optical electronic device 12 discussed above) is located, thereby, the display panel 110 can improve the transmittance of the at least one transmissive area TA without using the cathode patterning material. Further, the display panel 110 can maintain uniform emission efficiency by disposing a highly bondable organic cathode layer in at least one light emitting area EA.

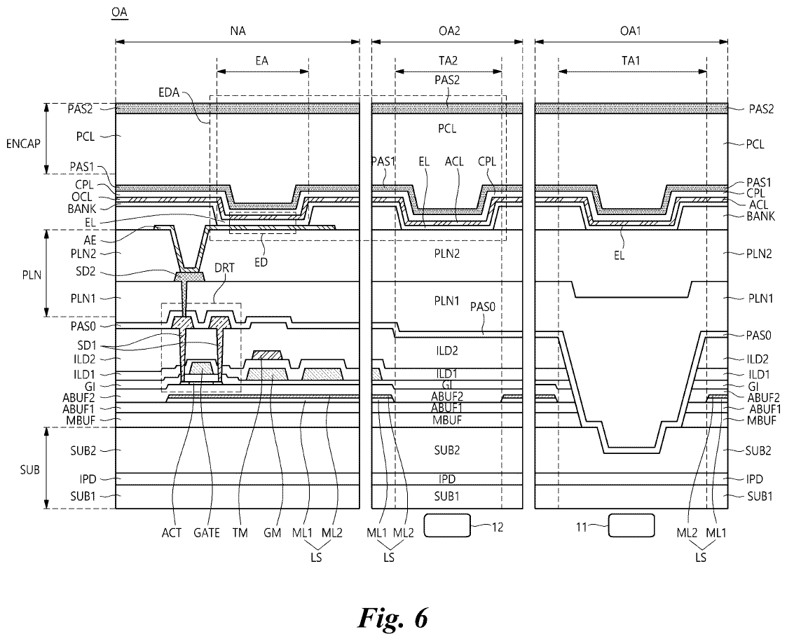

FIG. 6 is a cross-sectional view of an example optical area OA included in the display panel 110 according to some embodiments of the present disclosure.

Referring to FIG. 6, in one or more example embodiments, an optical area OA included in the display panel 110 may include at least one light emitting area EA, at least one first transmissive area TA1, and at least one second transmissive area TA2.

The at least one light emitting area EA included in the optical area OA may have the same or substantially same stack structure as at least one light emitting area EA in the normal area NA.

A substrate SUB may include a first substrate SUB1, an interlayer insulating layer IPD, and a second substrate SUB2. The interlayer insulating layer IPD may be located between the first substrate SUB1 and the second substrate SUB2. As the substrate SUB includes the first substrate SUB1, the interlayer insulating layer IPD, and the second substrate SUB2, the substrate SUB can prevent or reduce the penetration of moisture. The first substrate SUB1 and the second substrate SUB2 may be, for example, polyimide (PI) substrates. The first substrate SUB1 may be referred to as a primary PI substrate, and the second substrate SUB2 may be referred to as a secondary PI substrate.

Several types of patterns (ACT, SD1, and/or GATE) for forming one or more transistors such as a first transistor DRT, and the like, several types of insulating layers (MBUF, ABUF1, ABUF2, GI, ILD1, ILD2, and/or PAS0), and several types of metal patterns (TM, GM, ML1, and/or ML2) may be disposed on or over the substrate SUB of the at least one light emitting areas EA.

For example, a multi-buffer layer MBUF may be disposed on the second substrate SUB2, and a first active buffer layer ABUF1 may be disposed on the multi-buffer layer MBUF.

A first metal layer ML1 and a second metal layer ML2 may be disposed on the first active buffer layer ABUF1. For example, the first metal layer ML1 and the second metal layer ML2 may be light shield layers LS for shielding light.

A second active buffer layer ABUF2 may be disposed on the first metal layer ML1 and the second metal layer ML2. An active layer ACT of the driving transistor DRT may be disposed on the second active buffer layer ABUF2.

A gate insulating layer GI may be disposed such that it covers the active layer ACT.

A gate electrode GATE of the driving transistor DRT may be disposed on the gate insulating layer GI. Further, a gate material layer GM may be disposed on the gate insulating layer GI, together with the gate electrode GATE of the driving transistor DRT, at a location different from the location where the driving transistor DRT is disposed.

A first interlayer insulating layer ILD1 may be disposed such that it covers the gate electrode GATE and the gate material layer GM. A metal pattern TM may be disposed on the first interlayer insulating layer ILD1. The metal pattern TM may be disposed at a location different from the location where the driving transistor DRT is disposed. A second interlayer insulating layer ILD2 may be disposed such that it covers the metal pattern TM on the first interlayer insulating layer ILD1.

Two first source-drain electrode patterns SD1 may be disposed on the second interlayer insulating layer ILD2. One of the two first source-drain electrode patterns SDIs may be a source node of the driving transistor DRT, and the other thereof may be a drain node of the driving transistor DRT.

The two first source-drain electrode patterns SD1 may be electrically connected to first and second side portions of the active layer ACT, respectively, through contact holes formed in the second interlayer insulating layer ILD2, the first interlayer insulating layer ILD1, and the gate insulating layer GI.

A portion of the active layer ACT overlapping with the gate electrode GATE may serve as a channel region. One of the two first source-drain electrode patterns SD1 may be connected to the first side portion of the channel region of the active layer ACT, and the other of the two first source-drain electrode patterns SD1 may be connected to the second side portion of the channel region of the active layer ACT.

A passivation layer PAS0 may be disposed on the two first source-drain electrode patterns SDIs such that it covers the two first source-drain electrode patterns. A planarization layer PLN may be disposed on the passivation layer PAS0. The planarization layer PLN may include a first planarization layer PLN1 and a second planarization layer PLN2.

For example, the first planarization layer PLN1 may be disposed on the passivation layer PAS0.

A second source-drain electrode pattern SD2 may be disposed on the first planarization layer PLN1. The second source-drain electrode pattern SD2 may be connected to one of the two first source-drain electrode patterns SDIs through a contact hole formed in the first planarization layer PLN1.

The second planarization layer PLN2 may be disposed such that it covers the second source-drain electrode pattern SD2. A light emitting element ED of a subpixel SP may be disposed on the second planarization layer PLN2.

According to an example stackup configuration of the light emitting element ED, an anode electrode AE may be disposed on the second planarization layer PLN2. The anode electrode AE may be electrically connected to the second source-drain electrode pattern SD2 through a contact hole formed in the second planarization layer PLN2.

A bank BANK may be disposed on the anode electrode AE such that it covers a portion of the anode electrode AE. A portion of the bank BANK corresponding to a light emitting area EA of the subpixel SP may be opened.

A portion of the anode electrode AE may be exposed through the opening (the opened portion) of the bank BANK. An emission layer EL may be disposed on one or more side surfaces of the bank BANK and in the opening (the opened portion) of the bank BANK. All or at least part of the emission layer EL may be located between adjacent banks.

In the opening of the bank BANK, the emission layer EL may contact the anode electrode AE.

The emission layer EL may include a hole injection layer HIL, a hole transport layer HTL, an emission material layer EML, an electron transport layer ETL, and an electron injection layer EIL.

In some embodiments, to increase the emission efficiency of the light emitting element ED, the electron injection layer EIL may include a film-forming structure of ytterbium (Yb) and lithium fluoride (LiF).

An organic cathode layer OCL may be disposed on the emission layer EL of the light emitting area EA.

The organic cathode layer OCL may include a cohesive cathode electrode and at least one organic layer located on and/or underneath the cohesive cathode electrode.

The cohesive cathode electrode included in the organic cathode layer OCL may be formed to have a thickness less than or equal to a reference thickness so that self-aggregation of a metal material included in the cohesive cathode electrode can occur. For example, the reference thickness, at which the self-aggregation of the metal material of the cohesive cathode electrode can occur, may be about 20 nm.

To enable the self-aggregation of the cohesive cathode electrode, when the cohesive cathode electrode is formed to have a thickness of 20 nm or less, there may occur isolation in which a part of the cohesive cathode electrode is separated.

The at least one organic layer located on and/or underneath the cohesive cathode electrode may include a bondable organic material having a high bonding strength with a metal material of the cohesive cathode electrode so that the self-aggregation of the cohesive cathode electrode can be uniformly reconfigured.

The light emitting element ED can be formed by the anode electrode AE, the emission layer EL, and the organic cathode layer OCL.

In some embodiments, a capping layer CPL may be disposed on the light emitting element ED to improve light extraction and protect the light emitting element ED. The capping layer CPL may include an organic material having a low molecular structure.

An encapsulation layer ENCAP may be disposed on the capping layer CPL. The encapsulation layer ENCAP may have a single-layer structure or a multi-layer structure. For example, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic layers, and the second encapsulation layer PCL may be an organic layer. Among the first encapsulation layer PAS1, the second encapsulation layer PCL, and the third encapsulation layer PAS2, the second encapsulation layer PCL may be the thickest and serve as a planarization layer.

The first encapsulation layer PAS1 may be disposed on the organic cathode layer OCL and be disposed closest to the stack of the light emitting element ED. The first encapsulation layer PAS1 may include an inorganic insulating material capable of being deposited by low-temperature deposition. For example, the first encapsulation layer PAS1 may include, but not limited to, silicon nitride (SiNx), silicon oxide (SiOx), silicon oxynitride (SiON), aluminum oxide (Al2O3), or the like. Since the first encapsulation layer PAS1 is deposited in a low temperature atmosphere, during the deposition process, the first encapsulation layer PAS1 can prevent or reduce the emission layer EL including an organic material vulnerable to a high temperature atmosphere from being damaged.

The second encapsulation layer PCL may have a smaller area or size than the first encapsulation layer PAS1. For example, the second encapsulation layer PCL may be disposed such that it exposes both ends or edges of the first encapsulation layer PAS1. The second encapsulation layer PCL may serve as a buffer for relieving stress between corresponding layers while the display device 100 is curved or bent, and also serve to enhance planarization performance. For example, the second encapsulation layer PCL may include an organic insulating material, such as acrylic resin, epoxy resin, polyimide, polyethylene, silicon oxycarbon (SiOC), or the like. The second encapsulation layer PCL may be disposed, for example, by an inkjet technique.

The third encapsulation layer PAS2 may be disposed over the substrate SUB over which the second encapsulation layer PCL is disposed such that the third encapsulation layer PAS2 covers the respective top surfaces and side surfaces of the second encapsulation layer PCL and the first encapsulation layer PAS1. The third encapsulation layer PAS2 can minimize or prevent or reduce external moisture or oxygen from penetrating into the first encapsulation layer PAS1 and the second encapsulation layer PCL. For example, the third encapsulation layer PAS2 may include an inorganic insulating material, such as silicon nitride (SiNx), silicon oxide (SiOx), silicon oxynitride (SiON), aluminum oxide (Al2O3), or the like.

Hereinafter, a stackup configuration of the first transmissive area TA1 will be described.

As discussed above, while the organic cathode layer OCL capable of maintaining the uniformity of a metal material included in a cathode electrode CE may be disposed in the light emitting area EA, a cohesive cathode layer ACL (which may be referred to as a first cathode layer ACL) having a thickness less than or equal to a reference thickness at which self-aggregation of the metal material can occur may be disposed in the first transmissive area TA1.

To enable the self-aggregation of the cohesive cathode layer ACL, while the cohesive cathode layer ACL is formed to have a thickness of 20 nm or less, there may be formed an isolation area in which a part of the cohesive cathode layer ACL is separated.

As a result, light can be transmitted through the isolation area of the cohesive cathode layer ACL formed in the first transmissive area TA1, and therefore, the transmittance of the cohesive cathode layer ACL can be further improved.

The cohesive cathode layer ACL may include a cohesive cathode electrode, and an organic material may be disposed on and/or underneath the cohesive cathode electrode.

In some embodiments, a light shield layer LS including at least one of the first metal layer ML1 and the second metal layer ML2 may be disposed in the light emitting area EA, but the light shield layer LS may not be disposed in the first transmissive area TA1. In this configuration, the first transmissive area TA1 may correspond to an opening of the light shield layer LS.

The substrate SUB and several insulating layers (MBUF, ABUF1, ABUF2, GI, ILD1, ILD2, PAS0, PLN (PLN1 and PLN2), BANK, CPL, ENCAP (PAS1, PCL, and PAS2), T-BUF, T-ILD, and PAC) disposed in the light emitting area EA may be equally or substantially equally disposed in the first transmissive area TA1.

A bank BANK formed in the first transmissive area TA1 may be opened to form an opening, but some embodiments are not limited thereto. For example, when the bank BANK includes a transparent material, the bank BANK may be formed at a certain height substantially equal, or similar to, a height of the bank BANK in the light emitting area EA or an area adjacent to the light emitting area EA.

A capping layer CPL may be disposed on the cohesive cathode layer ACL to protect the first transmissive area TA1. The capping layer CPL may include an organic material with a low molecular structure.

In some embodiments, among layers stacked in the light emitting area EA, one or more material layers having electrical properties (e.g., metal material layers, a semiconductor layer, and the like) other than insulating materials may not be disposed in the first transmissive area TA1.

For example, the metal material layers (ML1, ML2, GATE, GM, TM, SD1, and SD2) and the active layer ACT related to the transistor (e.g., the driving transistor DRT) may not be disposed in the first transmissive area TA1.

Accordingly, as a material layer (e.g., a metal material layer, a semiconductor layer, etc.) having electrical properties is not disposed in the first transmissive area TA1, the first transmissive area TA1 can have capability to transmit light. Therefore, the first optical electronic device 11 can receive light passing through the first transmissive area TA1 and perform a corresponding function (e.g., image sensing).

It should be noted here that since all or at least a portion of the first transmissive area TA1 may overlaps with the first optical electronic device 11, to enable the first optical electronic device 11 to normally operate, it is desirable to further increase a transmittance of the first transmissive area TA1.

To achieve the foregoing, in some embodiments, the first transmissive area TA1 disposed in the first optical area OA1 included in the display panel 110 of the display device 100 may have a transmittance improvement structure TIS.

A plurality of insulating layers included in the display panel 110 may include at least one buffer layer (MBUF, ABUF1, ABUF2) between at least one substrate (SUB1, IPD, SUB2) and at least one transistor (DRT, SCT), at least one planarization layers (PLN1, PLN2) between the transistor DRT and the light emitting element ED, at least one encapsulation layer ENCAP on the light emitting element ED, and the like.

The first transmissive area TA1 can have a structure in which the first planarization layer PLN1 and the passivation layer PAS0 have depressed portions that extend downward from respective surfaces thereof as a transmittance improvement structure TIS.

Among the plurality of insulating layers, the first planarization layer PLN1 may include at least one depression (e.g., a recess, a trench, a concave portion, a protrusion, or the like). The first planarization layer PLN1 may be, for example, an organic insulating layer.

In the example where the first planarization layer PLN1 has the depressed portion that extends downward from the surfaces thereof, the second planarization layer PLN2 may substantially serve to provide planarization. In some embodiments, the second planarization layer PLN2 may also have a depressed portion that extends downward from the surface thereof. In this implementation, the second encapsulation layer PCL may substantially serve to provide planarization.

The depressed portions of the first planarization layer PLN1 and the passivation layer PAS0 may pass through insulating layers, such as the first interlayer insulating layer ILD1, the second interlayer insulating layer ILD2, the gate insulating layer GI, and the like, for forming the driving transistor DRT, and buffer layers, such as the first active buffer layer ABUF1, the second active buffer layer ABUF2, the multi-buffer layer MBUF, and the like, located under the insulating layers, and extend up to an upper portion of the second substrate SUB2.

The substrate SUB may include at least one concave portion or depressed portion as a transmittance improvement structure TIS. For example, in the first transmissive area TA1, an upper portion of the second substrate SUB2 may be indented or depressed downward, or the second substrate SUB2 may be perforated.

The first encapsulation layer PAS1 and the second encapsulation layer PCL included in the encapsulation layer ENCAP may also have a transmittance improvement structure TIS in which the first encapsulation layer PAS1 and the second encapsulation layer PCL have depressed portions that extend downward from the respective surfaces thereof. The second encapsulation layer PCL may be, for example, an organic insulating layer.

Hereinafter, a stackup configuration of the second transmissive area TA2 will be described.

As discussed above, while the organic cathode layer OCL capable of maintaining the uniformity of a metal material serving as a cathode electrode CE may be disposed in the light emitting area EA, a cohesive cathode layer ACL having a thickness less than or equal to a reference thickness at which self-aggregation of the metal material can occur may be disposed in the second transmissive area TA2.

In a similar situation to the first transmissive area TA1, to enable the self-aggregation of the cohesive cathode layer ACL, while the cohesive cathode layer ACL is formed to have a thickness of 20 nm or less, there may be formed an isolation area in which a part of the cohesive cathode layer ACL is separated.

As a result, light can be transmitted through the isolation area of the cohesive cathode layer ACL formed in the second transmissive area TA2, and therefore, the transmittance of the cohesive cathode layer ACL can be further improved.

In some embodiments, the light shield layer LS including at least one of the first metal layer ML1 and the second metal layer ML2 may be disposed in the light emitting area EA, but the light shield layer LS may not be disposed in the second transmissive area TA2. In this configuration, the second transmissive area TA2 may correspond to an opening of the light shield layer LS.

When a transmittance of the second transmissive area TA2 and a transmittance of the first transmissive area TA1 are the same as or similar to each other, a stackup configuration of the second transmissive area TA2 may be substantially the same as the stackup configuration of the first transmissive area TA1.

When the transmittance of the second transmissive area TA2 and the transmittance of the first transmissive area TA1 are different from each other, the stackup configuration of the second transmissive area TA2 may be different from the stackup configuration of the first transmissive area TA1.

For example, when the transmittance of the second transmissive area TA2 is less than the transmittance of the first transmissive area TA1, the second transmissive area TA2 may not have a transmittance improvement structure TIS. In this configuration, for example, the first planarization layer PLN1 and the passivation layer PAS0 may not be indented or depressed. Further, a width of the second transmissive area TA2 may be less than a width of the first transmissive area TA1.

The substrate SUB and several insulating layers (MBUF, ABUF1, ABUF2, GI, ILD1, ILD2, PAS0, PLN (PLN1 and PLN2), BANK, CPL, ENCAP (PAS1, PCL, and PAS2), T-BUF, T-ILD, and PAC) disposed in the light emitting area EA may be equally or substantially equally disposed in the second transmissive area TA2.

A bank BANK formed in the second transmissive area TA2 may be opened to form an opening, but some embodiments of the present disclosure are not limited thereto. For example, when the bank BANK includes a transparent material, the bank BANK may be formed at a certain height substantially equal, or similar to, a height of the bank BANK in the light emitting area EA or an area adjacent to the light emitting area EA.

In some embodiments, among layers stacked in the light emitting area EA, one or more material layers having electrical properties (e.g., metal material layers, a semiconductor layer, and the like) other than insulating materials may not be disposed in the second transmissive area TA2.

For example, the metal material layers (ML1, ML2, GATE, GM, TM, SD1, and SD2) and the active layer ACT related to the transistor (e.g., the driving transistor DRT) may not be disposed in the second transmissive area TA2.

The display panel 110 according to some embodiments of the present disclosure can maintain uniform emission efficiency by forming the cohesive cathode layer ACL having a thickness less than or equal to a reference thickness to improve transmittance through self-aggregation in the at least one transmissive area (TA1 and/or TA2) where the at least one optical electronic device (11 and/or 12) is placed, and by forming the organic cathode layer OCL in which a cohesive cathode electrode and an organic layer are stacked in the light emitting area EA.

Here, the cohesive cathode layer ACL formed in the at least one transmissive area (TA1 and/or TA2) may be referred to as a first cathode layer, and the organic cathode layer OCL formed in the light emitting area EA may be referred to as a second cathode layer.

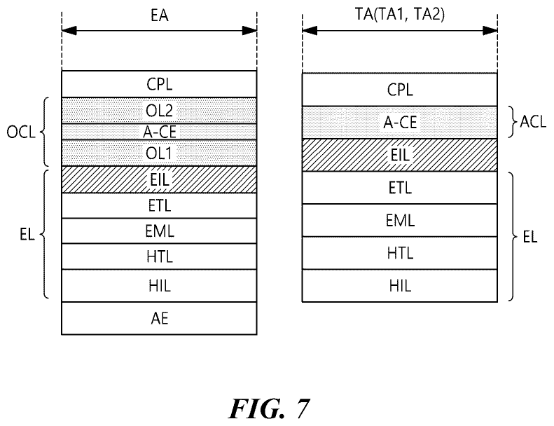

FIG. 7 illustrates example structures of a light emitting area and an area corresponding to the light emitting area in a transmissive area in the display panel according to some embodiments of the present disclosure.

Referring to FIG. 7, in one or more example embodiments, an optical area OA (e.g., the first optical area OA1 or the second optical area OA2 discussed above) defined in the display panel 110 may include at least one light emitting area EA and at least one transmissive area TA (e.g., the first transmissive area TA1 and/or the second transmissive area TA2). In some embodiments, at least one light emitting area EA of the normal area NA may have the same or substantially same structure as the at least one light emitting area EA of the optical area OA.

The light emitting area EA may include an anode electrode AE, an emission layer EL disposed on the anode electrode AE, and an organic cathode layer OCL disposed on the emission layer EL and overlapping with the emitting layer EL. A capping layer CPL may be disposed on the organic cathode layer OCL to protect the emission layer EL.

A light emitting element ED may be formed by the anode electrode AE, the emission layer EL, and the organic cathode layer OCL, and the light emitting element ED may be an organic light emitting element or an inorganic light emitting element depending on whether the emission layer EL is an organic emission layer EL or an inorganic emission layer EL.

The anode electrode AE disposed on a light emitting area EA of the light emitting element ED may be connected to a driving transistor and receive an electrical signal therefrom.

The anode electrode AE may include a conductive material having a relatively large work function value. For example, the anode electrode AE may include ITO, IZO, ITZO, SnO, ZnO, ICO, AZO, and/or a combination thereof.

The emission layer EL may include a hole injection layer HIL, a hole transport layer HTL, an emission material layer EML, an electron transport layer ETL, and an electron injection layer EIL. Further, the emission layer EL may further include an electron blocking layer EBL and a hole blocking layer HBL.

The hole injection layer HIL may be located between the anode electrode AE and the hole transport layer HTL, and can improve an interface characteristic between the anode electrode AE and the hole transport layer HTL. For example, the hole injection layer HIL may include MTDATA, NATA, ITNATA, 2T-NATA, CuPc, TCTA, NPB(NPD), DNTPD, HAT-CN, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB, MgF2, CaF2, and/or a combination thereof.

The hole transport layer HTL can supply holes to the emission material layer EML. The hole transport layer HTL may include TPD, NPB, DNTPD, BPBPA, CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl) biphenyl)-4-amine, N-([1,1′-biphenyl]-4-yl)-9,9-dimethyl-N-(4-(9-phenyl-9H-carbazol-3-yl)phenyl)-9H-fluoren-2-amine, and/or a combination thereof.

The emission material layer EML may include a red emission material layer, a green emission material layer, and a blue emission material layer.

The electron transport layer ETL can supply electrons to the emission material layer EML. The electron transport layer ETL may include any one of an oxadiazole-based compound, a triazole-based compound, a phenanthroline-based compound, a benzoxazole-based compound, a benzothiazole-based compound, a benzimidazole-based compound, and a triazine-based compound.

The electron injection layer EIL may be located between the organic cathode layer OCL and the electron transport layer ETL, and can improve the characteristic of the organic cathode layer OCL and the lifetime of the light emitting element ED. The electron injection layer EIL may include an alkali metal halide-based material such as LiF, CsF, NaF, BaF2, or the like, and/or an alkaline earth metal halide-based material, and/or an organometallic material such as Liq, lithium benzoate, sodium stearate, or the like.

In some embodiments, to increase the emission efficiency of the light emitting element ED, the electron injection layer EIL may include a film-forming structure of ytterbium (Yb) and lithium fluoride (LiF).

The organic cathode layer OCL may include a cohesive cathode electrode A-CE and at least one bondable organic layer (OL1 and/or OL2) located on and/or underneath the cohesive cathode electrode A-CE. FIG. 7 illustrates an example where a first bondable organic layer OL1 is located underneath the cohesive cathode electrode A-CE and a second bondable organic layer OL2 is located on the cohesive cathode electrode A-CE.

The cohesive cathode electrode A-CE may include a material having a relatively low work function value. For example, the cohesive cathode electrode A-CE may include aluminum (Al), magnesium (Mg), calcium (ca), silver (Ag), an alloy thereof, or a combination thereof (for example, a material having good reflective properties such as an aluminum-magnesium alloy (AlMg)).

The cohesive cathode electrode A-CE may be formed at a thickness less than or equal to a certain reference thickness at which self-aggregate of a metal material (e.g., silver (Ag)) included in the cohesive cathode electrode A-CE can occur. For example, the reference thickness, at which the self-aggregation of the metal material of the cohesive cathode electrode A-CE can occur, may be about 20 nm.

The at least one bondable organic layer (OL1 and/or OL2) located on and/or underneath the cohesive cathode electrode A-CE may include an organic material having a high bonding strength with a metal material of the cohesive cathode electrode A-CE so that the self-aggregation of the cohesive cathode electrode A-CE can be uniformly reconfigured.

For example, when the cohesive cathode electrode A-CE including silver (Ag) is deposited with a thickness of 20 nm or less, to enable a material included in the at least one bondable organic layer (OL1 and/or OL2) to be bonded to silver (Ag) and maintain a uniform structure, the at least one bondable organic layer (OL1 and/or OL2) may include an organic material, as a functional group, having phenanthroline, BPhen (2,6-bis(1,H-benzimidazol-2-yl)-4-methylphenol), HAT-CN, indazole, benzoic acid, polymethyl methacrylate (PMMA), thiocyanate, carboxylic acid, or polyacrylonitrile (PAN).

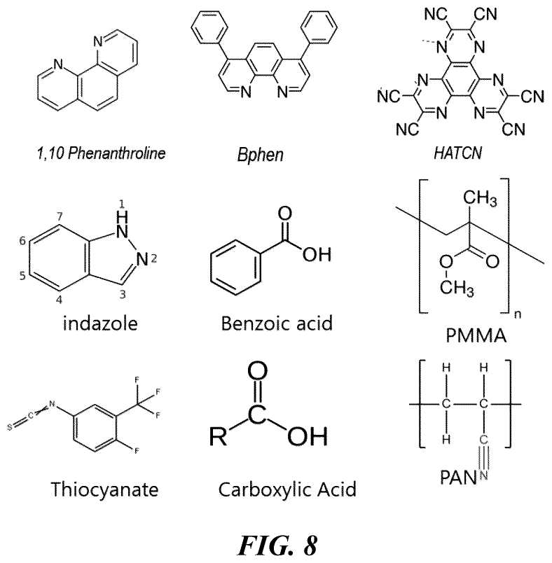

FIG. 8 illustrates an example molecular structure of at least one bondable organic layer located on and/or underneath a cohesive cathode electrode in a light emitting area of the display panel 110 according to some embodiments.

When a metal material included in the cohesive cathode electrode A-CE is changed from one material to another material, an organic compound used in each of the first bondable organic layer OL1 and the second bondable organic layer OL2 may also be changed.

Referring back to FIG. 7, a transmissive area TA (e.g., the transmissive area TA1 or the second transmissive area TA discussed above) where an optical electronic device (e.g., the first optical electronic device 11 or the second optical electronic device 12 discussed above) is located may include an emission layer EL and a cohesive cathode layer ACL disposed on the emission layer EL. A capping layer CPL may be disposed on the cohesive cathode layer ACL.

The emission layer EL located in the transmissive area TA may have the same or substantially same structure as the emission layer EL located in the light emitting area EA. In contrast, since an anode electrode is not disposed under the emission layer EL in the transmissive area TA, the emission layer EL of the transmissive area TA cannot emit light that can be seen by a user.

Therefore, an electron injection layer EIL included in the emission layer EL of the transmissive area TA may include an alkali metal halide-based material such as LiF, CsF, NaF, BaF2, or the like, and/or an alkaline earth metal halide-based material, and/or an organometallic material such as Liq, lithium benzoate, sodium stearate, or the like. In some embodiments, the electron injection layer EIL may include a film-forming structure of ytterbium (Yb) and lithium fluoride (LiF).

The cohesive cathode layer ACL may include a cohesive cathode electrode A-CE.

The cohesive cathode electrode A-CE may include a material having a relatively low work function value. For example, the cohesive cathode electrode A-CE may include aluminum (Al), magnesium (Mg), calcium (ca), silver (Ag), an alloy thereof, and/or a combination thereof (for example, a material having good reflective properties such as an aluminum-magnesium alloy (AlMg)).

The cohesive cathode electrode A-CE may be formed at a thickness less than or equal to a certain reference thickness at which self-aggregate of a metal material (e.g., silver (Ag)) included in the cohesive cathode electrode A-CE can occur. For example, the reference thickness, at which the self-aggregation of the metal material of the cohesive cathode electrode A-CE can occur, may be about 20 nm.

Here, the emission layer EL, the cohesive cathode layer ACL, and the capping layer CPL, which are formed in the transmissive area TA, may be referred to as a first emission layer, a first cathode layer, and a first capping layer, respectively. Further, the emission layer EL, the organic cathode layer OCL, and the capping layer CPL, which are formed in the light emitting area EA, may be referred to as a second emission layer, a second cathode layer, and a second capping layer, respectively. Further, the cohesive cathode electrode A-CE included in the cohesive cathode layer ACL may be referred to as a first cathode electrode, and the cohesive cathode electrode A-CE included in the organic cathode layer OCL may be referred to as a second cathode electrode.

In some embodiments, the first cathode electrode included in the cohesive cathode layer ACL of the transmissive area TA and the second cathode electrode included in the organic cathode layer OCL of the light emitting area EA may be formed with the same or substantially same thickness or may be formed with different thicknesses.

When the cathode electrodes of the transmissive area TA and the light emitting area EA are formed through the same or substantially same process, associated process may be simplified. Therefore, herein, discussions are provided for an example where the first cathode electrode included in the cohesive cathode layer ACL of the transmissive area TA and the second cathode electrode included in the organic cathode layer OCL of the light emitting area EA are cohesive cathode electrodes A-CE of the same or substantially same thickness (20 nm or less) formed through the same or substantially same process.

As discussed above, the transmittance of the light emitting area EA can be improved by forming the cohesive cathode electrode A-CE with a thickness less than or equal to a reference thickness at which self-aggregation of a metal material included in the cohesive cathode electrode A-CE can occur in the transmissive area TA where the optical electronic device (11, 12) is located.

In addition, when the cohesive cathode electrode A-CE is formed in the transmissive area TA, since a cathode patterning material need not be used, the emission efficiency of a corresponding light emitting area EA can be improved by using a fluorine-based compound such as lithium fluoride (LiF) in the electron injection layer EIL under the cohesive cathode electrode A-CE.

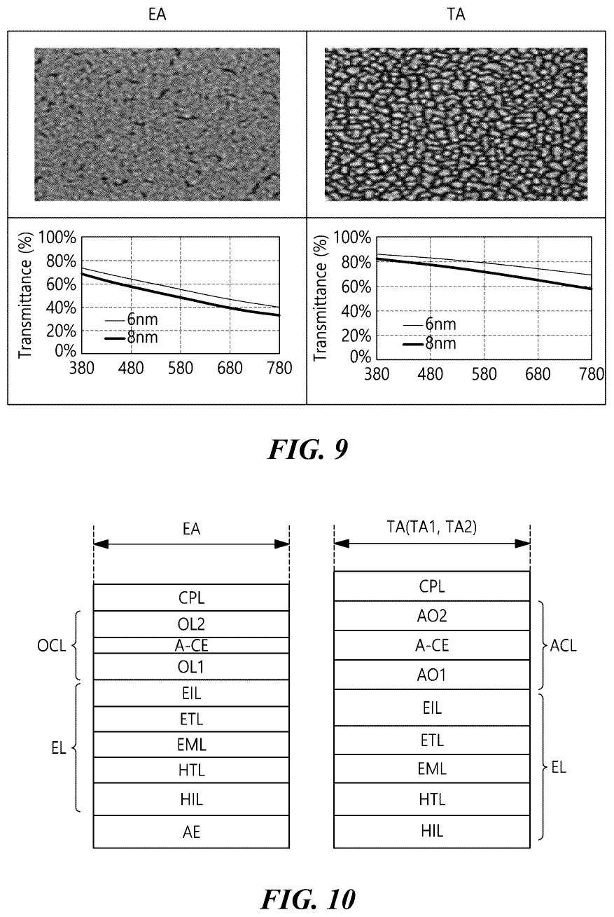

FIG. 9 illustrates electron micrographs and transmittance of a light emitting area and a transmissive area including a cohesive cathode electrode in the display panel 110 according to some embodiments.

Referring to FIG. 9, in one or more example embodiments, the display panel 110 may include a cohesive cathode electrode A-CE with a thickness at which self-aggregate can occur in a transmissive area TA (e.g., the transmissive area TA1 or the second transmissive area TA discussed above) where an optical electronic device (e.g., the first optical electronic device 11 or the second optical electronic device 12 discussed above) is located. FIG. 9 illustrates examples where the cohesive cathode electrode A-CE is formed with thicknesses of 6 nm and 8 nm.

It can be seen that that the transmittance of the transmissive area TA can be improved by forming the cohesive cathode electrode A-CE with a thickness at which self-aggregation can occur in the transmissive area TA.

Further, since the display panel 110 does not use a cathode patterning material, the emission efficiency of a corresponding light emitting area EA can be improved by using a fluorine-based compound such as lithium fluoride (LiF) in an electron injection layer EIL included in an emission layer EL under the cohesive cathode electrode A-CE.

In some embodiments, the display panel 110 may further include at least one cohesive organic layer capable of maintaining a cohesive state of a metal material disposed on and/or underneath a cohesive cathode electrode A-CE in the transmissive area TA.

FIG. 10 illustrates another example structures of a light emitting area and an area corresponding to the light emitting area in a transmissive area in the display panel 110 according to some embodiments of the present disclosure.

Referring to FIG. 10, in one or more example embodiments, an optical area OA (e.g., the first optical area OA1 or the second optical area OA2 discussed above) defined in the display panel 110 may include at least one light emitting area EA and at least one transmissive area TA (e.g., the first transmissive area TA1 and/or the second transmissive area TA2). In some embodiments, at least one light emitting area EA of the normal area NA may have the same or substantially same structure as the at least one light emitting area EA of the optical area OA.

The light emitting area EA may include an anode electrode AE, an emission layer EL disposed on the anode electrode AE, and an organic cathode layer OCL disposed on the emission layer EL and overlapping with the emitting layer EL. A capping layer CPL may be disposed on the organic cathode layer OCL to protect the emission layer EL.

The structure of the light emitting area EA in FIG. 10 may be the same, or substantially the same, as that of FIG. 7, and therefore, corresponding discussions are omitted or may be briefly provided for simplicity.

The transmissive area TA where the optical electronic device (11 or 12) is located may include an emission layer EL and a cohesive cathode layer ACL. A capping layer CPL may be disposed on the cohesive cathode layer ACL.

The emission layer EL located in the transmissive area TA may have the same or substantially same structure as the emission layer EL located in the light emitting area EA.

Therefore, an electron injection layer EIL included in the emission layer EL of the transmissive area TA may include an alkali metal halide-based material such as LiF, CsF, NaF, BaF2, or the like, and/or an alkaline earth metal halide-based material, and/or an organometallic material such as Liq, lithium benzoate, sodium stearate, or the like. In some embodiments, the electron injection layer EIL may include a film-forming structure of ytterbium (Yb) and lithium fluoride (LiF).

The cohesive cathode layer ACL may include a cohesive cathode electrode A-CE and at least one cohesive organic layer (AO1 and/or AO2) located on and/or underneath the cohesive cathode electrode A-CE. FIG. 10 illustrates an example where a lower cohesive organic layer AO1 is located underneath the cohesive cathode electrode A-CE and an upper cohesive organic layer AO2 is located on the cohesive cathode electrode A-CE. Here, the cohesive organic layers (AO1 and AO2) may be referred to as first organic layers, and the bondable organic layers (OL1 and OL2) may be referred to as second organic layer 2.

The cohesive cathode electrode A-CE may include a material having a relatively low work function value. For example, the cohesive cathode electrode A-CE may include aluminum (Al), magnesium (Mg), calcium (ca), silver (Ag), an alloy thereof, and/or a combination thereof (for example, a material having good reflective properties such as an aluminum-magnesium alloy (AlMg)).

The cohesive cathode electrode A-CE may be formed at a thickness less than or equal to a certain reference thickness at which self-aggregate of a metal material (e.g., silver (Ag)) included in the cohesive cathode electrode A-CE can occur. For example, the reference thickness, at which the self-aggregation of the metal material of the cohesive cathode electrode A-CE may occur, may be about 20 nm.

The at least one cohesive organic layer (AO1 and/or AO2) located on and/or underneath the cohesive cathode electrode A-CE in the transmissive area TA may include an organic material that is difficult to bond with a metal material of the cohesive cathode electrode A-CE so that the self-aggregation behavior of the cohesive cathode electrode A-CE can be maintained.

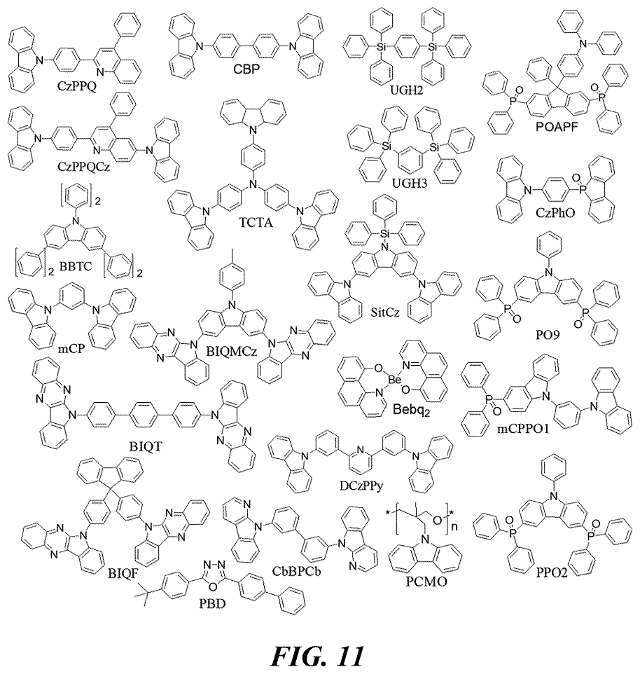

FIG. 11 illustrates an example molecular structure of a cohesive organic layer located on or underneath a cohesive cathode electrode in a transmissive area of the display panel 110 according to some embodiments.

When a metal material included in the cohesive cathode electrode A-CE is changed from one material to another material, a material used in each cohesive organic layers (AO1, AO2) may also be changed.

In some embodiments, the display panel 110 can improve the characteristics of an electron injection layer EIL and the conductivity characteristics by forming a stack of two or more cohesive cathode electrodes A-CE to improve the transmittance of the transmissive area TA.

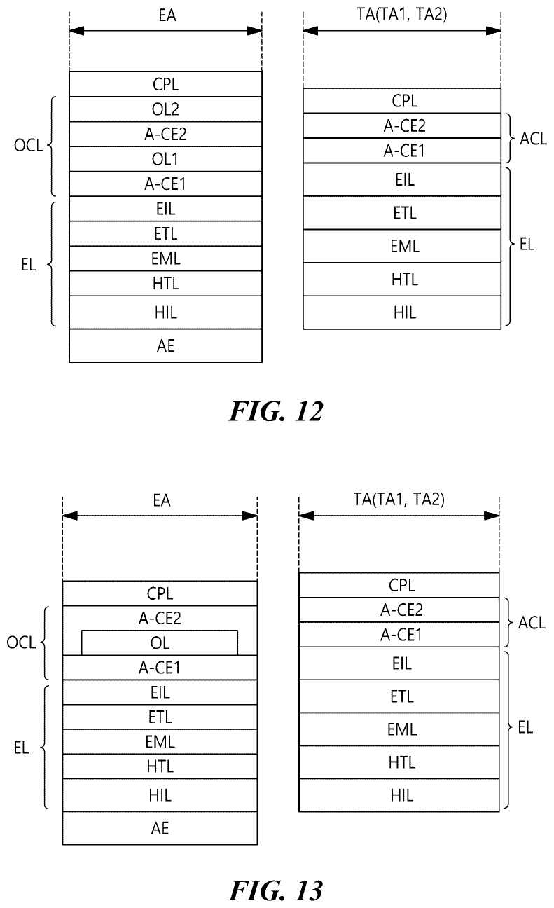

FIG. 12 illustrates an example structure including a cathode electrode of a stack structure in a light emitting area and a transmissive area of the display panel according some embodiments.

Referring to FIG. 12, in one or more example embodiments, an optical area OA (e.g., the first optical area OA1 or the second optical area OA2 discussed above) defined in the display panel 110 may include at least one light emitting area EA and at least one transmissive area TA (e.g., the first transmissive area TA1 and/or the second transmissive area TA2). In some embodiments, at least one light emitting area EA of the normal area NA may have the same or substantially same structure as the at least one light emitting area EA of the optical area OA.

The light emitting area EA may include an anode electrode AE, an emission layer EL disposed on the anode electrode AE, and an organic cathode layer OCL disposed on the emission layer EL and overlapping with the emitting layer EL. A capping layer CPL may be disposed on the organic cathode layer OCL to protect the emission layer EL.

Configurations of the anode electrode AE and the emission layer EL in FIG. 12 may be the same, or substantially the same, as that of FIG. 7, and therefore, corresponding discussions are omitted or may be briefly provided for simplicity.

An organic cathode layer OCL may have a structure in which a cohesive cathode electrode A-CE and a bondable organic layer are alternately laminated.

For example, the organic cathode layer OCL may include a first cohesive cathode electrode A-CE1, a first bondable organic layer OL1 located on the first cohesive cathode electrode A-CE1, a second cohesive cathode electrode A-CE2 located on the first bondable organic layer OL1, and a second bondable organic layer OL2 located on the second cohesive cathode electrode A-CE2.

The first cohesive cathode electrode A-CE1 and the second cohesive cathode electrode A-CE2 may include a material having a relatively low work function value. For example, the first cohesive cathode electrode A-CE1 and the second cohesive cathode electrode A-CE2 may include aluminum (Al), magnesium (Mg), calcium (ca), silver (Ag), an alloy thereof, and/or a combination thereof (for example, a material having good reflective properties such as an aluminum-magnesium alloy (AlMg)).

The first cohesive cathode electrode A-CE1 and the second cohesive cathode electrode A-CE2 may be formed to have a thickness less than or equal to a predetermined reference thickness so that self-aggregation of a metal material (for example, silver (Ag)) therein can occur. The total thickness of the first cohesive cathode electrode A-CE1 and the second cohesive cathode electrode A-CE2 may be about 20 nm at which the self-aggregation of the metal material (for example, silver (Ag)) therein can occur.

The first bondable organic layer OL1 and the second bondable organic layer OL2 may include an organic material having a high bonding strength with a metal material of the first cohesive cathode electrode A-CE1 and the second cohesive cathode electrode A-CE2 so that the self-aggregation of the first cohesive cathode electrode A-CE1 and the second cohesive cathode electrode A-CE2 can be uniformly reconfigured.

For example, when the first cohesive cathode electrode A-CE1 and the second cohesive cathode electrode A-CE2 including silver (Ag) are deposited with a thickness of 20 nm or less, to enable a material included in each of the first bondable organic layer OL1 and the second bondable organic layer OL2 to be bonded to silver (Ag) and maintain a uniform structure, each of the first bondable organic layer OL1 and the second bondable organic layer OL2 may include an organic material, as a functional group, having phenanthroline, BPhen (2,6-bis(1,H-benzimidazol-2-yl)-4-methylphenol), HAT-CN, indazole, benzoic acid, polymethyl methacrylate (PMMA), thiocyanate, carboxylic acid, or polyacrylonitrile (PAN).

When a metal material included in each of the first cohesive cathode electrode A-CE1 and the second cohesive cathode electrode A-CE2 is changed from one material to another material, an organic compound used in each of the first bondable organic layer OL1 and the second bondable organic layer OL2 may also be changed.

The at least one transmissive area TA (e.g., the first transmissive area TA1 and/or the second transmissive area TA2) in which at least one optical electronic device (e.g., the first optical electronic device 11 and/or the second optical electronic device 12) may include an emission layer EL, a first cohesive cathode electrode A-CE1 and a second cohesive cathode electrode A-CE2 located on the emission layer EL.

The first cohesive cathode electrode A-CE1 and the second cohesive cathode electrode A-CE2 of the transmissive area TA may be formed by the same or substantially same process as the first cohesive cathode electrode A-CE1 and the second cohesive cathode electrode A-CE2 of the light emitting area EA.

A capping layer CPL may be disposed on the first cohesive cathode electrode A-CE1 and the second cohesive cathode electrode A-CE2.

The emission layer EL located in the transmissive area TA may have the same or substantially same structure as the emission layer EL located in the light emitting area EA.

Therefore, an electron injection layer EIL included in the emission layer EL of the transmissive area TA may include an alkali metal halide-based material such as LiF, CsF, NaF, BaF2, or the like, and/or an alkaline earth metal halide-based material, and/or an organometallic material such as Liq, lithium benzoate, sodium stearate, or the like. In some embodiments, the electron injection layer EIL may include a film-forming structure of ytterbium (Yb) and lithium fluoride (LiF).

The first cohesive cathode electrode A-CE1 and the second cohesive cathode electrode A-CE2 may be formed to have a thickness less than or equal to a predetermined reference thickness so that self-aggregation of a metal material (for example, silver (Ag)) therein can occur. The total thickness of the first cohesive cathode electrode A-CE1 and the second cohesive cathode electrode A-CE2 may be about 20 nm at which the self-aggregation of the metal material (for example, silver (Ag)) therein can occur.

In some embodiments, the display panel 110 may further include a cohesive organic layer capable of maintaining a cohesive state of a metal material disposed on and/or underneath the first cohesive cathode electrode A-CE1 and the second cohesive cathode electrode A-CE2 in the transmissive area TA.

In some embodiments, in the display panel 110, the organic cathode layer OCL of the light emitting area may include a cohesive cathode electrode A-CE of a stack structure in which a bondable organic layer OL is interposed between the cohesive cathode electrodes (A-CE1 and A-CE2.

FIG. 13 illustrates another example structure including a cathode electrode of a stack structure in a light emitting area and a transmissive area of the display panel according to some embodiments of the present disclosure.

Referring to FIG. 13, in one or more example embodiments, an optical area OA (e.g., the first optical area OA1 or the second optical area OA2 discussed above) defined in the display panel 110 may include at least one light emitting area EA and at least one transmissive area TA (e.g., the first transmissive area TA1 and/or the second transmissive area TA2). In some embodiments, at least one light emitting area EA of the normal area NA may have the same or substantially same structure as the at least one light emitting area EA of the optical area OA.

The light emitting area EA may include an anode electrode AE, an emission layer EL disposed on the anode electrode AE, and an organic cathode layer OCL disposed on the emission layer EL and overlapping with the emitting layer EL. A capping layer CPL may be disposed on the organic cathode layer OCL to protect the emission layer EL.

Configurations of the anode electrode AE and the emission layer EL in FIG. 13 may be the same, or substantially the same, as that of FIG. 7, and therefore, corresponding discussions are omitted or may be briefly provided for simplicity.

The organic cathode layer OCL may include a bondable organic layer OL interposed between a first cohesive cathode electrode A-CE1 and a second cohesive cathode electrode A-CE2.

For example, the organic cathode layer OCL may include the first cohesive cathode electrode A-CE1, the bondable organic layer OL located on a portion of the first cohesive cathode electrode A-CE1, and the second cohesive cathode electrode A-CE2 disposed such that the second cohesive cathode electrode A-CE2 covers the bondable organic layer OL.

The first cohesive cathode electrode A-CE1 and the second cohesive cathode electrode A-CE2 may include a material having a relatively low work function value. For example, the first cohesive cathode electrode A-CE1 and the second cohesive cathode electrode A-CE2 may include aluminum (Al), magnesium (Mg), calcium (ca), silver (Ag), an alloy thereof, and/or a combination thereof (for example, a material having good reflective properties such as an aluminum-magnesium alloy (AlMg)).

The first cohesive cathode electrode A-CE1 and the second cohesive cathode electrode A-CE2 may be formed to have a thickness less than or equal to a predetermined reference thickness so that self-aggregation of a metal material (for example, silver (Ag)) therein can occur. The total thickness of the first cohesive cathode electrode A-CE1 and the second cohesive cathode electrode A-CE2 may be about 20 nm at which the self-aggregation of the metal material (for example, silver (Ag)) therein can occur.

The bondable organic layer OL may include an organic material having a high bonding strength with a metal material of the first cohesive cathode electrode A-CE1 and the second cohesive cathode electrode A-CE2 so that the self-aggregation of the first cohesive cathode electrode A-CE1 and the second cohesive cathode electrode A-CE2 can be uniformly reconfigured.

For example, when the first cohesive cathode electrode A-CE1 and the second cohesive cathode electrode A-CE2 including silver (Ag) are deposited with a thickness of 20 nm or less, to enable a material included in the bondable organic layer OL to be bonded to silver (Ag) and maintain a uniform structure, the bondable organic layer OL may include an organic material, as a functional group, having phenanthroline, BPhen (2,6-bis(1,H-benzimidazol-2-yl)-4-methylphenol), HAT-CN, indazole, benzoic acid, polymethyl methacrylate (PMMA), thiocyanate, carboxylic acid, or polyacrylonitrile (PAN).

When a metal material included in each of the first cohesive cathode electrode A-CE1 and the second cohesive cathode electrode A-CE2 is changed from one material to another material, an organic compound used in the bondable organic layer OL may also be changed.

The structure of the at least one transmissive area TA (e.g., the first transmissive area TA1 and/or the second transmissive area TA2) in which at least one optical electronic device (e.g., the first optical electronic device 11 and/or the second optical electronic device 12) may be the same, or substantially the same, as that of FIG. 12, and therefore, corresponding discussions are omitted or may be briefly provided for simplicity.

In some embodiments, in the display panel 110, the organic cathode layer OCL of the light emitting area may include a cohesive cathode electrode A-CE of a stack structure in which a bondable organic layer OL having a pattern form is interposed between the cohesive cathode electrodes (A-CE1 and A-CE2.

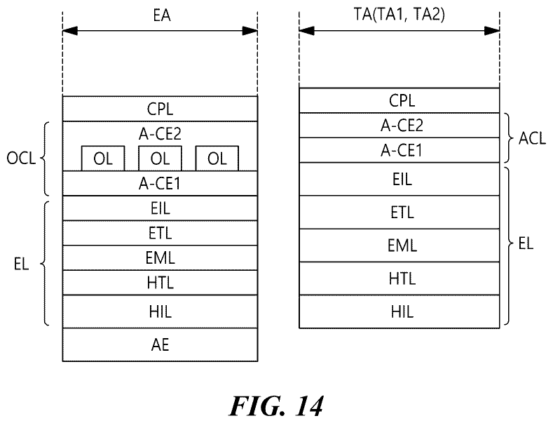

FIG. 14 illustrates an example structure including a bondable organic layer having a pattern form and a cathode electrode of a stack structure in a light emitting area and a transmissive area of the display panel according to some embodiments of the present disclosure.

Referring to FIG. 14, in one or more example embodiments, an optical area OA (e.g., the first optical area OA1 or the second optical area OA2 discussed above) defined in the display panel 110 may include at least one light emitting area EA and at least one transmissive area TA (e.g., the first transmissive area TA1 and/or the second transmissive area TA2). In some embodiments, at least one light emitting area EA of the normal area NA may have the same or substantially same structure as the at least one light emitting area EA of the optical area OA.

The light emitting area EA may include an anode electrode AE, an emission layer EL disposed on the anode electrode AE, and an organic cathode layer OCL disposed on the emission layer EL and overlapping with the emitting layer EL. A capping layer CPL may be disposed on the organic cathode layer OCL to protect the emission layer EL.

Configurations of the anode electrode AE and the emission layer EL in FIG. 13 may be the same, or substantially the same, as that of FIG. 7, and therefore, corresponding discussions are omitted or may be briefly provided for simplicity.

The organic cathode layer OCL may include a bondable organic layer OL interposed between a first cohesive cathode electrode A-CE and a second cohesive cathode electrode A-CE2, and having a pattern form.

For example, the organic cathode layer OCL may include the first cohesive cathode electrode A-CE1, the bondable organic layer OL located on a portion of the first cohesive cathode electrode A-CE1 and having a pattern form, and the second cohesive cathode electrode A-CE2 disposed such that the second cohesive cathode electrode A-CE2 covers the bondable organic layer OL.

The first cohesive cathode electrode A-CE1 and the second cohesive cathode electrode A-CE2 may include a material having a relatively low work function value. For example, the first cohesive cathode electrode A-CE1 and the second cohesive cathode electrode A-CE2 may include aluminum (Al), magnesium (Mg), calcium (ca), silver (Ag), an alloy thereof, and/or a combination thereof (for example, a material having good reflective properties such as an aluminum-magnesium alloy (AlMg)).

The first cohesive cathode electrode A-CE1 and the second cohesive cathode electrode A-CE2 may be formed to have a thickness less than or equal to a predetermined reference thickness so that self-aggregation of a metal material (for example, silver (Ag)) therein can occur. The total thickness of the first cohesive cathode electrode A-CE1 and the second cohesive cathode electrode A-CE2 may be about 20 nm at which the self-aggregation of the metal material (for example, silver (Ag)) therein can occur.

The bondable organic layer OL may include an organic material having a high bonding strength with a metal material of the first cohesive cathode electrode A-CE1 and the second cohesive cathode electrode A-CE2 so that the self-aggregation of the first cohesive cathode electrode A-CE1 and the second cohesive cathode electrode A-CE2 can be uniformly reconfigured.

For example, when the first cohesive cathode electrode A-CE1 and the second cohesive cathode electrode A-CE2 including silver (Ag) are deposited with a thickness of 20 nm or less, to enable a material included in the bondable organic layer OL to be bonded to silver (Ag) and maintain a uniform structure, the bondable organic layer OL may include an organic material, as a functional group, having phenanthroline, BPhen (2,6-bis(1,H-benzimidazol-2-yl)-4-methylphenol), HAT-CN, indazole, benzoic acid, polymethyl methacrylate (PMMA), thiocyanate, carboxylic acid, or polyacrylonitrile (PAN).

When a metal material included in each of the first cohesive cathode electrode A-CE1 and the second cohesive cathode electrode A-CE2 is changed from one material to another material, an organic compound used in the bondable organic layer OL may also be changed.

The structure of the at least one transmissive area TA (e.g., the first transmissive area TA1 and/or the second transmissive area TA2) in which at least one optical electronic device (e.g., the first optical electronic device 11 and/or the second optical electronic device 12) may be the same, or substantially the same, as that of FIG. 12, and therefore, corresponding discussions are omitted or may be briefly provided for simplicity.

Meanwhile, in the display panel 110, when a cohesive cathode electrode A-CE of a stack structure is located on the emission layer EL, an influence on an electron injection layer EIL under the cohesive cathode electrode A-CE may be reduced by the cohesive cathode electrode A-CE.

Therefore, in this case, by disposing a metal patterning material for suppressing the deposition of an additional metal layer on the cohesive cathode electrode A-CE of the stack structure, the process of forming one or more subsequent metal layers may be performed.

As discussed above, the display panel can provide advantages of improving the transmittance of the at least one transmissive area TA by forming the cohesive cathode electrode A-CE with a thickness at which self-aggregation can occur in the at least one transmissive area TA where the at least one optical electronic devices (11 and/or 12) are located.

In addition, when the cohesive cathode electrode A-CE is formed in the transmissive area TA, since a cathode patterning material need not be used, the emission efficiency of a corresponding light emitting area EA can be improved by using a fluorine-based compound such as lithium fluoride (LiF) in the electron injection layer EIL under the cohesive cathode electrode A-CE.

Various embodiments of the present disclosure will be described below.

According to the one or more example embodiments described herein, a display device can be provided that includes a display panel including an optical area in which at least one transmissive area and at least one light emitting area are defined, and a normal area located outside of the optical area and including a plurality of light emitting areas, a gate driving circuit configured to supply at least one gate signal to the display panel, a data driving circuit configured to convert image data into a data voltage and supplying the resulted data voltage to the display panel, and a display controller configured to control the gate driving circuit and the data driving circuit. In some embodiments, the at least one transmissive area may include an emission layer, a cohesive cathode layer disposed with a reference thickness at which self-aggregation occurs on the emission layer, and a capping layer disposed on the cohesive cathode layer.

In some embodiments, the emission layer may include a hole injection layer, a hole transport layer, an emission material layer, an electron transport layer, and an electron injection layer, and the electron injection layer may include a film structure of ytterbium (Yb) and lithium fluoride (LiF).

In some embodiments, the cohesive cathode layer may include silver (Ag) or an alloy of silver (Ag).

In some embodiments, the cohesive cathode layer may include a structure in which

two or more cathode electrodes are stacked.

In some embodiments, wherein the reference thickness may be 20 nm or less.

In some embodiments, the cohesive cathode layer may further include a cohesive organic layer located on or underneath the cohesive cathode electrode, and a material included in the cohesive cathode layer does not recombine with a metal material included in the cohesive cathode electrode.

In some embodiments, the emission layer may further include a metal patterning material disposed on the cohesive cathode layer to suppress deposition of a metal layer.

In some embodiments, the light emitting area may include an anode electrode, a second emission layer disposed on the anode electrode, an organic cathode layer disposed on the second emission layer and allowing an organic material and a cathode electrode to be stacked, and a capping layer disposed on the organic cathode layer.

In some embodiments, the second emission layer may include a hole injection layer, a hole transport layer, an emission material layer, an electron transport layer, and an electron injection layer, and the electron injection layer may include a film structure of ytterbium (Yb) and lithium fluoride (LiF).

In some embodiments, the second emission layer may be formed by a same or substantially same process as the emission layer of the transmissive area.

In some embodiments, the organic cathode layer may include a first cohesive cathode electrode and a bondable organic layer disposed on or underneath the first cohesive cathode electrode.

In some embodiments, the first cohesive cathode electrode may include silver (Ag) or an alloy of silver (Ag), and the bondable organic layer may be an organic material, as a functional group, having phenanthroline, BPhen (2,6-bis(1,H-benzimidazol-2-yl)-4-methylphenol), HAT-CN, indazole, benzoic acid, polymethyl methacrylate (PMMA), thiocyanate, carboxylic acid, or polyacrylonitrile (PAN).

In some embodiments, a thickness of the first cohesive cathode electrode may be 20 nm or less.

In some embodiments, the organic cathode layer may include a first cohesive cathode electrode, a bondable organic layer disposed on the first cohesive cathode electrode, and a second cohesive cathode electrode disposed on the bondable organic layer.

In some embodiments, the bondable organic layer may be disposed on a portion of the first cohesive cathode electrode, and the second cohesive cathode electrode may be disposed to cover the bondable organic layer.

In some embodiments, the bondable organic layer may be disposed in a pattern form on the first cohesive cathode electrode, and the second cohesive cathode electrode may be disposed to cover the bondable organic layer.

In some embodiments, the organic cathode layer may further include a metal patterning material to suppress deposition of a metal layer.

According to the one or more example embodiments described herein, a display panel can be provided that includes a display area including an optical area in which at least one transmissive area and at least one light emitting area are defined, and a normal area located outside of the optical area and including a plurality of light emitting areas. In some embodiments, the at least one transmissive area may include a first emission layer, a cohesive cathode layer disposed with a reference thickness at which self-aggregation occurs on the first emission layer, and a first capping layer disposed on the cohesive cathode layer, and the at least one light emitting area and at least one of the plurality of light emitting areas may include an anode electrode, a second emission layer disposed on the anode electrode, an organic cathode layer disposed on the second emission layer and allowing an organic material and a cathode electrode to be stacked, and a second capping layer disposed on the organic cathode layer.

In some embodiments, the first emission layer and the second emission layer may have the same or substantially same structure.

In some embodiments, the first cohesive cathode electrode included in the cohesive cathode layer and the second cohesive cathode electrode included in the organic cathode layer may be formed with the same or substantially same thickness.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes only. That is, the disclosed embodiments are intended to illustrate the scope of the technical features of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display panel comprising:
a display area comprising an optical area and a normal area, in the optical area at least one transmissive area and at least one light emitting area are defined, and the normal area located outside of the optical area and the normal area including a plurality of light emitting areas,
wherein the at least one transmissive area comprises:
a first emission layer; and
a first cathode layer disposed on the first emission layer, the first cathode layer having a first thickness, and the first cathode layer comprising a first cathode electrode, and
wherein the light emitting areas in the optical area and the normal area comprise:
an anode electrode;
a second emission layer disposed on the anode electrode; and
a second cathode layer disposed on the second emission layer, and the second cathode layer allowing an organic material and a second cathode electrode to be stacked.

2. The display panel of claim 1, wherein each of the first emission layer and the second emission layer comprises a hole injection layer, a hole transport layer, an emission material layer, an electron transport layer, and an electron injection layer, and
wherein the electron injection layer comprises a film structure of ytterbium (Yb) and lithium fluoride (LiF).

3. The display panel of claim 1, wherein the first cathode layer comprises an isolation area in which a part of the first cathode layer is separated.

4. The display panel of claim 1, wherein the first thickness is equal to or less than 20 nm.

5. The display panel of claim 1, wherein the first cathode electrode comprises silver (Ag) or an alloy of silver (Ag).

6. The display panel of claim 1, wherein the first cathode layer comprises a structure in which two or more first cathode electrodes are stacked.

7. The display panel of claim 1, wherein the first cathode layer further comprises a first organic layer located on or underneath the first cathode electrode, and a material included in the first organic layer does not recombine with a metal material included in the first cathode electrode.

8. The display panel of claim 1, wherein the first emission layer further comprises a metal patterning material disposed on the first cathode layer to suppress deposition of a metal layer.

9. The display panel of claim 1, wherein the transmissive area further comprises a first capping layer disposed on the first cathode layer.

10. The display panel of claim 1, wherein the second emission layer is formed by a same process as the first emission layer.

11. The display panel of claim 1, wherein the second cathode layer includes a second organic layer disposed on or underneath the second cathode electrode.

12. The display panel of claim 11, wherein the second cathode electrode comprises silver (Ag) or an alloy of silver (Ag), and
when the second organic layer is an organic material, as a functional group, having phenanthroline, BPhen (2,6-bis(1,H-benzimidazol-2-yl)-4-methylphenol), HAT-CN, indazole, benzoic acid, polymethyl methacrylate (PMMA), thiocyanate, carboxylic acid, or polyacrylonitrile (PAN).

13. The display panel of claim 11, wherein a thickness of the second cathode electrode is equal to or less than 20 nm.

14. The display panel of claim 1, wherein the second cathode electrode is formed with a same thickness, and through a same process, as the first cathode electrode.

15. The display panel of claim 1, wherein the second cathode layer comprises:
a second organic layer disposed on the second cathode electrode; and
a third cathode electrode disposed on the second organic layer.

16. The display panel of claim 15, wherein the second organic layer is disposed on a portion of the second cathode electrode, and the third cathode electrode is disposed such that the third cathode electrode covers the second organic layer.

17. The display panel of claim 15, wherein the second organic layer is disposed in a pattern form on the second cathode electrode, and the third cathode electrode is disposed such that the third cathode electrode covers the second organic layer.

18. The display panel of claim 1, wherein the second cathode layer further comprises a metal patterning material for suppressing deposition of a metal layer.

19. The display panel of claim 1, wherein the light emitting area further comprises a second capping layer disposed on the second cathode layer.

20. A display device comprising:
a display panel comprising a display area comprising an optical area and a normal area, in the optical area at least one transmissive area and at least one light emitting area are defined, and the normal area located outside of the optical area and the normal area including a plurality of light emitting areas; and
a gate driving circuit configured to supply at least one gate signal to the display panel,
wherein the at least one transmissive area comprises:
a first emission layer; and
a first cathode layer disposed on the first emission layer, the first cathode layer having a first thickness, and the first cathode layer comprising a first cathode electrode, and
wherein the light emitting areas in the optical area and the normal area comprises:
an anode electrode;
a second emission layer disposed on the anode electrode; and
a second cathode layer disposed on the second emission layer, and the second cathode layer allowing an organic material and a second cathode electrode to be stacked.
